(19) United States
(12) Patent Application Publication
(10) Pub. No.: US 2025/0386689 A1
(43) Pub. Date: Dec. 18, 2025

(54) DISPLAY DEVICE, METHOD OF MANUFACTURING THE DISPLAY DEVICE, AND ELECTRONIC DEVICE INCLUDING THE SAME

(71) Applicant: Samsung Display Co., LTD., Yongin-si (KR)

(72) Inventors: SUNKWANG KIM, Yongin-si (KR); SI HYUN AHN, Yongin-si (KR); KYEUK LEE, Yongin-si (KR); SEONGYOUNG LEE, Yongin-si (KR)

(73) Assignee: Samsung Display Co., LTD., Yongin-si (KR)

(21) Appl. No.: 19/071,166

(22) Filed: Mar. 5, 2025

(30) Foreign Application Priority Data
Jun. 18, 2024 (KR) 10-2024-0078838

(51) Int. Cl. H10K 59/131; H01L 23/00; H01L 23/498; H10K 59/12; H10K 59/95

(52) U.S. Cl. CPC H10K 59/131; H01L 23/49838; H01L 24/06; H10K 59/1201; H10K 59/95; H01L 2223/54426; H01L 2224/06152

(57) ABSTRACT

A display device includes: a substrate including a display area where multiple pixels are disposed and a pad area spaced apart from the display area, a first substrate pad disposed in the pad area and forming a first inclination angle with an edge of the substrate to have an inclined shape, a substrate alignment mark disposed in the pad area and adjacent to the first substrate pad, a first alignment pattern disposed in the pad area and disposed below the first substrate pad in a plan view, and a chip-on-film attached to a side of the substrate. The chip-on-film includes a first film pad overlapping the first substrate pad in a plan view in at least a portion of the pad area and forming a second inclination angle with the edge of the substrate to have an inclined shape and a film alignment mark adjacent to the first film pad.

### CROSS-REFERENCE TO RELATED APPLICATION(S)

This application claims priority to and benefits of Korean Patent Application No. 10-2024-0078838 under 35 U.S.C. § 119, filed on Jun. 18, 2024, in the Korean Intellectual Property Office, the entire contents of which are incorporated herein by reference.

### BACKGROUND

### 1. Technical Field

Embodiments relate to a display device, a method of manufacturing the display device, and an electronic device including the display device. More particularly, embodiments relate to a display device including a chip-on-film, a method of manufacturing the display device, and an electronic device including the display device.

### 2. Description of the Related Art

A display device is a device that displays an image for providing visual information to a user. Among display devices, an organic light emitting diode display device has recently attracted attention.

The display device may include a substrate on which a plurality of pixels are disposed and a chip-on-film attached to a side of the substrate. It is necessary to check whether the substrate and the chip-on-film are properly aligned. For example, in case that the chip-on-film is attached to the substrate in an expanded or contracted state, it is necessary to check the chip-on-film and adjust position of the chip-on-film.

### SUMMARY

Embodiments provide a display device with improved quality.

Embodiments provide a method of manufacturing the display device.

Embodiments provide an electronic device including the display device.

A display device according to an embodiment includes a substrate including a display area in which a plurality of pixels are disposed and a pad area spaced apart from the display area, a first substrate pad disposed in the pad area on the substrate and forming a first inclination angle with respect to an edge of the substrate to have an inclined shape, a substrate alignment mark disposed in the pad area on the substrate and adjacent to the first substrate pad, a first alignment pattern disposed in the pad area on the substrate and disposed below the first substrate pad in a plan view, and a chip-on-film attached to a side of the substrate.

In an embodiment, the chip-on-film may include a first film pad overlapping the first substrate pad in a plan view in at least a portion of the pad area and forming a second inclination angle with respect to the edge of the substrate to have an inclined shape and a film alignment mark adjacent to the first film pad.

In an embodiment, the first inclination angle and the second inclination angle may be substantially equal to each other.

In an embodiment, the first alignment pattern may form a third inclination angle with respect to the edge of the substrate.

In an embodiment, the third inclination angle and the first inclination angle may be substantially equal to each other.

In an embodiment, the substrate alignment mark may be disposed adjacent to the first substrate pad in a first direction.

In an embodiment, the film alignment mark may be disposed adjacent to the first film pad in the first direction.

In an embodiment, the first alignment pattern may be disposed adjacent to the first film pad in the first direction in a plan view.

In an embodiment, the display device may further include a second alignment pattern spaced apart from the first alignment pattern in a plan view with the first film pad disposed between the second alignment pattern and the first alignment pattern.

In an embodiment, the first alignment pattern may form a third inclination angle with respect to the edge of the substrate to have an inclined shape.

In an embodiment, the second alignment pattern may form a fourth inclination angle with respect to the edge of the substrate.

In an embodiment, the third inclination angle and the fourth inclination angle may be substantially equal to each other.

In an embodiment, the display device may further include a second substrate pad disposed in the pad area on the substrate, disposed adjacent to the first substrate pad, and forming a third inclination angle with respect to the edge of the substrate to have an inclined shape.

In an embodiment, the chip-on-film may further include a second film pad overlapping the second substrate pad in a plan view in at least a portion of the pad area and forming a fourth inclination angle with respect to the edge of the substrate.

In an embodiment, the third inclination angle and the fourth inclination angle may be substantially equal to each other.

In an embodiment, the display device may further include a second alignment pattern disposed in the pad area on the substrate and spaced apart from the first alignment pattern in a plan view with the first film pad interposed therebetween, a third alignment pattern disposed between the second alignment pattern and the second film pad in a plan view, and a fourth alignment pattern disposed in the pad area on the substrate and spaced apart from the third alignment pattern in a plan view with the second film pad interposed therebetween.

In an embodiment, the third alignment pattern may form a fifth inclination angle with respect to the edge of the substrate to have an inclined shape.

In an embodiment, the fourth alignment pattern may form a sixth inclination angle with respect to the edge of the substrate.

In an embodiment, the fifth inclination angle and the sixth inclination angle may be substantially equal to each other.

In an embodiment, the first alignment pattern may be a portion from which at least a portion of an insulating layer disposed on the first substrate pad is removed.

A method of manufacturing a display device according to an embodiment includes attaching a chip-on-film to a side of a substrate including a display area in which a plurality of pixels are disposed and a pad area spaced apart from the display area, checking a substrate alignment mark disposed in the pad area on the substrate and a film alignment mark included in the chip-on-film to check whether the chip-on-film is expanded and whether the chip-on-film is contracted, adjusting position of the chip-on-film, and measuring a first separation distance between a first film pad and a first alignment pattern adjacent to the first film pad.

In an embodiment, the first film pad may be included in the chip-on-film and may form a first inclination angle with respect to an edge of the substrate to have an inclined shape in at least a portion of the pad area.

In an embodiment, the adjusting of the position of the chip-on-film may include moving the chip-on-film in a direction away from the substrate in case that the chip-on-film is expanded.

In an embodiment, the adjusting of the position of the chip-on-film may include moving the chip-on-film so that an area where the chip-on-film and the substrate overlap in a plan view increases in case that the chip-on-film is contracted.

In an embodiment, the method may further include additionally adjusting the position of the chip-on-film after measuring the first separation distance between the first film pad and the first alignment pattern.

An electronic device according to an embodiment includes a substrate including a display area in which a plurality of pixels are disposed and a pad area spaced apart from the display area, a first substrate pad disposed in the pad area on the substrate and forming a first inclination angle with respect to an edge of the substrate to have an inclined shape, a substrate alignment mark disposed in the pad area on the substrate and adjacent to the first substrate pad, a first alignment pattern disposed in the pad area on the substrate and disposed below the first substrate pad in a plan view, a chip-on-film attached to a side of the substrate, and a memory where data information is stored.

The first inclination angle and the second inclination angle may be substantially equal to each other.

The first alignment pattern may form a third inclination angle with respect to the edge of the substrate, and the third inclination angle and the first inclination angle may be substantially equal to each other.

The substrate alignment mark may be adjacent to the first substrate pad in a first direction, and the film alignment mark may be adjacent to the first film pad in the first direction.

In an embodiment, the chip-on-film may include a first film pad overlapping the first substrate pad in a plan view in at least a portion of the pad area and forming a second inclination angle with respect to the edge of the substrate to have an inclined shape and a film alignment mark adjacent to the first film pad.

A display device according to an embodiment may include a substrate including a display area in which a plurality of pixels are disposed and a pad area spaced apart from the display area, a first substrate pad disposed in the pad area on the substrate and forming a first inclination angle with respect to the edge of the substrate to have an inclined shape, a substrate alignment mark disposed in the pad area on the substrate and adjacent to the first substrate pad, a first alignment pattern disposed in the pad area on the substrate and disposed below the first substrate pad in a plan view, and a chip-on-film attached to a side of the substrate. The chip-on-film may include a first film pad overlapping the first substrate pad in a plan view in at least a portion of the pad area and forming a second inclination angle with respect to the edge of the substrate to have an inclined shape and a film alignment mark adjacent to the first film pad.

By measuring a separation distance between the first alignment pattern and the first film pad, it may be precisely determined whether the chip-on-film is properly attached to a side of the substrate. For example, as the display device includes the first alignment pattern, it may be precisely determined whether the chip-on-film is properly attached to a side of the substrate.

### BRIEF DESCRIPTION OF THE DRAWINGS

Illustrative, non-limiting embodiments will be more clearly understood from the following detailed description in conjunction with the accompanying drawings.

FIG. 1 is a schematic plan view illustrating a display device according to embodiments.

FIG. 2 is an enlarged schematic plan view illustrating an example of an X1 area of FIG. 1.

FIG. 3 is an enlarged schematic plan view illustrating an example of an X2 area of FIG. 1.

FIG. 4 is an enlarged schematic plan view of an X3 area of FIG. 2.

FIG. 5 is an enlarged schematic plan view of an X4 area of FIG. 4.

FIG. 6 is a schematic cross-sectional view illustrating pixels included in the display device of FIG. 1.

FIGS. 7 and 8 are schematic plan views illustrating a case in which a chip-on-film included in the display device of FIG. 1 is expanded.

FIGS. 9 and 10 are schematic plan views illustrating the chip-on-film disposed at an adjusted position.

FIG. 11 is an enlarged schematic plan view illustrating an X5 area of FIG. 9.

FIG. 12 is an enlarged schematic plan view illustrating an X6 area of FIG. 10.

FIGS. 13 and 14 are schematic plan views illustrating a case in which the chip-on-film included in the display device of FIG. 1 is contracted.

FIGS. 15 and 16 are schematic plan views illustrating the chip-on-film disposed at an adjusted position.

FIG. 17 is an enlarged schematic plan view illustrating an X7 area of FIG. 15.

FIG. 18 is an enlarged schematic plan view illustrating an X8 area of FIG. 16.

FIG. 19 is an enlarged schematic plan view illustrating an example of an X1 area of FIG. 1.

FIG. 20 is an enlarged schematic plan view illustrating an example of an X2 area of FIG. 1.

FIG. 21 is a schematic block diagram illustrating an electronic device according to embodiments.

FIG. 22 is a schematic diagram of an electronic device according to various embodiments.

### DETAILED DESCRIPTION OF THE EMBODIMENTS

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. In case that an embodiment may be implemented differently, a specific process order may be performed differently from the described order. For example, two consecutively described processes may be performed substantially at the same time or performed in an order opposite to the described order. Also, like reference numerals and/or reference characters denote like elements.

In case that an element, such as a layer, is referred to as being “on,” “connected to,” or “coupled to” another element or layer, it may be directly on, connected to, or coupled to the other element or layer or intervening elements or layers may be present. In case that, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another. For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” in case that used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the inventive concepts. Further, the blocks, units, and/or modules of some embodiments may be physically combined into more complex blocks, units, and/or modules without departing from the scope of the inventive concepts.

Hereinafter, display devices in accordance with embodiments will be described in more detail with reference to the accompanying drawings. The same reference numerals are used for the same components in the drawings, and redundant descriptions of the same components will be omitted.

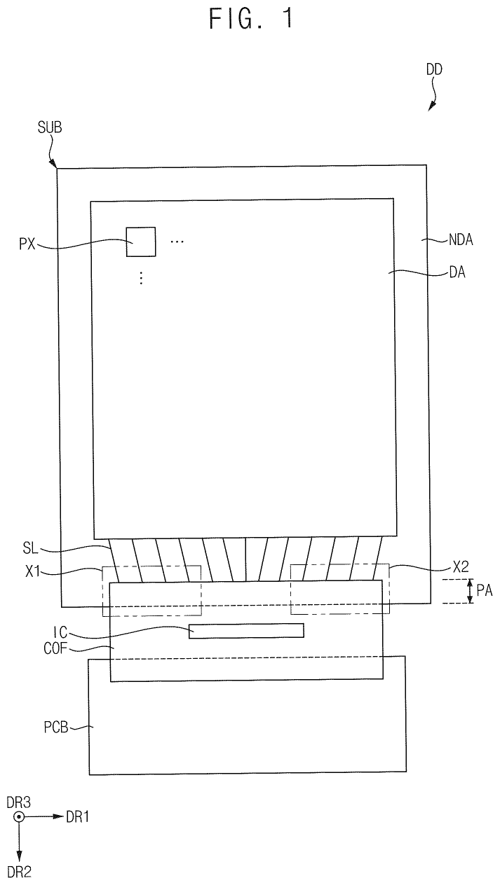

FIG. 1 is a schematic plan view illustrating a display device according to embodiments.

Referring to FIG. 1, a display device DD according to embodiments may include a substrate SUB, a chip-on-film COF, and a circuit board PCB.

The substrate SUB may include a display area DA and a non-display area NDA. The display area DA may be defined as an area emitting light. The non-display area NDA may be defined as an area in which components transmitting signals to the display area DA are disposed.

Multiple pixels may be disposed in the display area DA. For example, a pixel PX may be disposed in the display area DA. Each of multiple pixels PX may emit light based on a signal applied from the non-display area NDA. For example, multiple pixels PX may be repeatedly arranged in a first direction DR1 and a second direction DR2 crossing the first direction DR1. Accordingly, the display area DA may emit light over entire area and display an image.

The non-display area NDA may contact the display area DA. For example, the non-display area NDA may be disposed around the display area DA. For example, the non-display area NDA may surround at least a portion of the display area DA.

The non-display area NDA may include a pad area PA. The pad area PA may be disposed on a side (e.g., single side) of the non-display area NDA. For example, the pad area PA may be spaced apart from the display area DA in a plan view. For example, the pad area PA may be spaced apart from the display area DA in the second direction DR2. For example, the non-display area NDA may surround the display are DA.

The non-display area NDA may include drivers for driving multiple pixels PX. For example, the non-display area NDA may include a gate driver, a light emitting driver, a power voltage generator, and/or the like.

The chip-on-film COF may be attached to a side (e.g., single side) of the substrate SUB. For example, the chip-on-film COF may be attached to the substrate SUB in at least a portion of the pad area PA. For example, the chip-on-film COF may be spaced apart from the display area DA in the second direction DR2.

The number of chip-on-film COF may be one. However, the disclosure is not limited thereto, and the number of chip-on-film COF may be changed. For example, the number of chip-on-film COF may be two or more.

The number of chip-on-film COF may be one. However, the disclosure is not limited thereto, and the number of chip-on-film COF may be changed. For example, the number of chip-on-film COF may be two or more.

For example, the chip-on-film COF may include a soft material. For example, the chip-on-film COF may include polyethyleneterephthalate (“PET”), polyimide (“PI”), and/or the like. These materials may be used alone or in combination with each other. However, the disclosure is not limited thereto, and the chip-on-film COF may include a different kind of material.

The driving chip IC may be disposed on the chip-on-film COF. The driving chip IC may convert a digital data signal among driving signals into an analog data signal. The driving chip IC may provide the analog data signal to multiple pixels PX.

The circuit board PCB may be attached to a side (e.g., single side) of the chip-on-film COF. For example, the circuit board PCB may be spaced apart from the substrate SUB in the second direction DR2. The circuit board PCB may provide a driving signal, a driving voltage, and/or the like to the driving chip IC and multiple pixels PX.

The number of circuit board PCB may be one. However, the disclosure is not limited thereto, and the number of circuit board PCB may be changed. For example, the number of circuit board PCB may be two or more.

Signal provided from the chip-on-film COF and the circuit board PCB may be provided to the substrate SUB through multiple connection lines SL. For example, the signal provided from the chip-on-film COF and the circuit board PCB may be provided to the display area DA through multiple connection lines SL. However, the disclosure is not limited thereto, and the signal provided from the chip-on-film COF and the circuit board PCB through multiple connection lines SL may also be provided to the non-display area NDA.

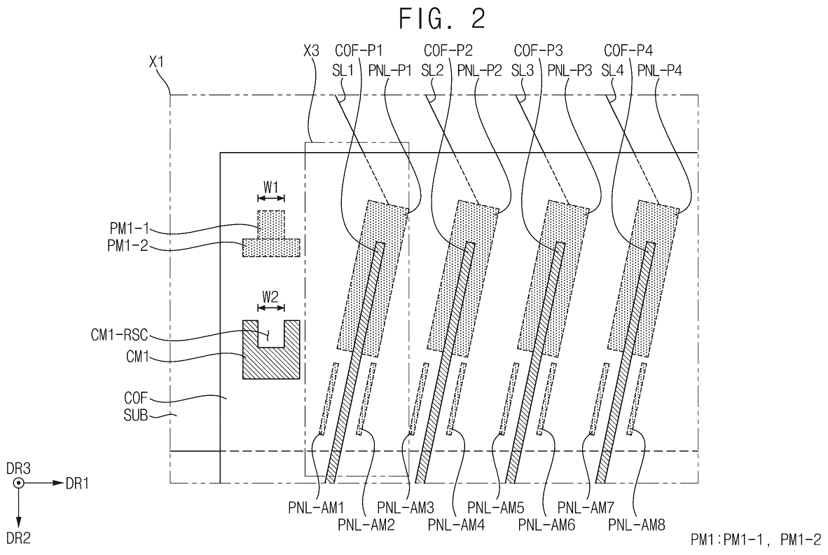

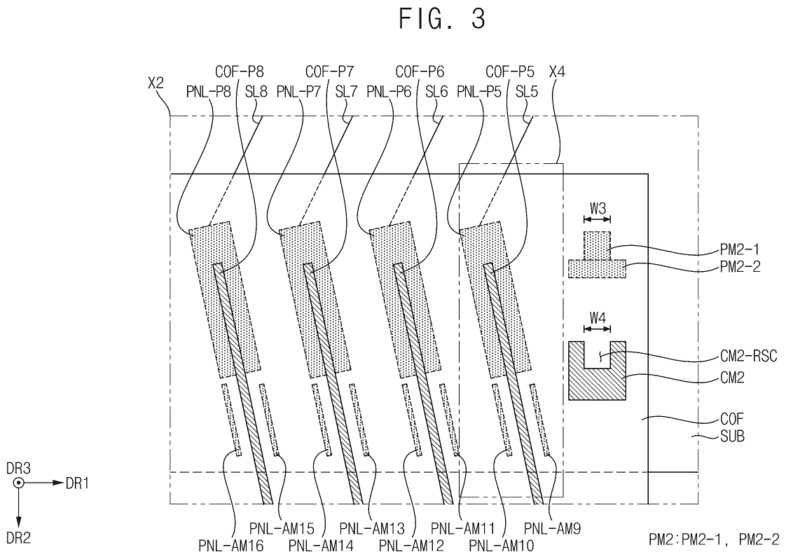

FIG. 2 is an enlarged schematic plan view illustrating an example of an X1 area of FIG. 1. FIG. 3 is an enlarged schematic plan view illustrating an example of an X2 area of FIG. 1.

Referring to FIGS. 1, 2, and 3, multiple substrate pads may be disposed on the substrate SUB. For example, a first substrate pad PNL-P1, a second substrate pad PNL-P2, a third substrate pad PNL-P3, a fourth substrate pad PNL-P4, a fifth substrate pad PNL-P5, a sixth substrate pad PNL-P6, a seventh substrate pad PNL-P7, and an eighth substrate pad PNL-P8 may be disposed on the substrate SUB.

For example, the first substrate pad PNL-P1, the second substrate pad PNL-P2, the third substrate pad PNL-P3, the fourth substrate pad PNL-P4, the fifth substrate pad PNL-P5, the sixth substrate pad PNL-P6, the seventh substrate pad PNL-P7, and the eighth substrate pad PNL-P8 may be disposed in the pad area PA.

For example, the first substrate pad PNL-P1, the second substrate pad PNL-P2, the third substrate pad PNL-P3, and the fourth substrate pad PNL-P4 may be disposed on a side (e.g., single side) of the pad area PA. For example, the fifth substrate pad PNL-P5, the sixth substrate pad PNL-P6, the seventh substrate pad PNL-P7, and the eighth substrate pad PNL-P8 may be disposed on another side of the pad area PA. For example, another side of the pad area PA may be spaced apart from the side of the pad area PA in the first direction DR1.

Multiple substrate pads may be repeatedly disposed in the first direction DR1. For example, the second substrate pad PNL-P2 may be disposed adjacent to the first substrate pad PNL-P1 in the first direction DR1. The third substrate pad PNL-P3 may be disposed adjacent to the second substrate pad PNL-P2 in the first direction DR1. The fourth substrate pad PNL-P4 may be disposed adjacent to the third substrate pad PNL-P3 in the first direction DR1.

For example, the sixth substrate pad PNL-P6 may be disposed adjacent to the fifth substrate pad PNL-P5 in a direction opposite to the first direction DR1. The seventh substrate pad PNL-P7 may be disposed adjacent to the sixth substrate pad PNL-P6 in the direction opposite to the first direction DR1. The eighth substrate pad PNL-P8 may be disposed adjacent to the seventh substrate pad PNL-P7 in the direction opposite to the first direction DR1.

Multiple connection line SL may include a first connection line SL1, a second connection line SL2, a third connection line SL3, a fourth connection line SL4, a fifth connection line SL5, a sixth connection line SL6, a seventh connection line SL7, and an eighth connection line SL8.

The first substrate pad PNL-P1 may be electrically connected to the first connection line SL1. The second substrate pad PNL-P2 may be electrically connected to the second connection line SL2. The third substrate pad PNL-P3 may be electrically connected to the third connection line SL3. The fourth substrate pad PNL-P4 may be electrically connected to the fourth connection line SL4. The fifth substrate pad PNL-P5 may be electrically connected to the fifth connection line SL5. The sixth substrate pad PNL-P6 may be electrically connected to the sixth connection line SL6. The seventh substrate pad PNL-P7 may be electrically connected to the seventh connection line SL7. The eighth substrate pad PNL-P8 may be electrically connected to the eighth connection line SL8.

A first substrate alignment mark PM1 may be disposed on the substrate SUB. The first substrate alignment mark PM1 may be disposed in the pad area PA. For example, the first substrate alignment mark PM1 may be disposed adjacent to the first substrate pad PNL-P1. For example, the first substrate alignment mark PM1 may be disposed adjacent to the first substrate pad PNL-P1 in the direction opposite to the first direction DR1.

For example, the first substrate alignment mark PM1 may include a first portion PM1-1 and a second portion PM1-2. The first portion PM1-1 may be attached to a central portion of the second portion PM1-2. For example, the first portion PM1-1 may contact the second portion PM1-2 in a direction opposite to the second direction DR2.

The first portion PM1-1 may have a rectangular shape in a plan view. However, the disclosure is not limited thereto, and shape of the first portion PM1-1 may be changed. The second portion PM1-2 may have a rectangular shape in a plan view. For example, the second portion PM1-2 may have a rectangular shape extending in the first direction DR1 in a plan view. However, the disclosure is not limited thereto, and shape of the second portion PM1-2 may be changed.

A second substrate alignment mark PM2 may be disposed on the substrate SUB. The second substrate alignment mark PM2 may be disposed in the pad area PA. For example, the second substrate alignment mark PM2 may be disposed adjacent to the fifth substrate pad PNL-P5. For example, the second substrate alignment mark PM2 may be disposed adjacent to the fifth substrate pad PNL-P5 in the first direction DR1.

For example, the second substrate alignment mark PM2 may include a first portion PM2-1 and a second portion PM2-2. The first portion PM2-1 may be attached to a central portion of the second portion PM2-2. For example, the first portion PM2-1 may contact the second portion PM2-2 in the direction opposite to the second direction DR2.

The first portion PM2-1 may have a rectangular shape in a plan view. However, the disclosure is not limited thereto, and shape of the first portion PM2-1 may be changed. The second portion PM2-2 may have a rectangular shape in a plan view. For example, the second portion PM2-2 may have a rectangular shape extending in the first direction DR1 in a plan view. However, the disclosure is not limited thereto, and shape of the second portion PM2-2 may be changed.

Multiple alignment patterns may be disposed on the substrate SUB. For example, a first alignment pattern PNL-AM1, a second alignment pattern PNL-AM2, a third alignment pattern PNL-AM3, a fourth alignment pattern PNL-AM4, a fifth alignment pattern PNL-AM5, a sixth alignment pattern PNL-AM6, a seventh alignment pattern PNL-AM7, an eighth alignment pattern PNL-AM8, a ninth alignment pattern PNL-AM9, a tenth alignment pattern PNL-AM10, an eleventh alignment pattern PNL-AM11, a twelfth alignment pattern PNL-AM12, a thirteenth alignment pattern PNL-AM13, a fourteenth alignment pattern PNL-AM14, a fifteenth alignment pattern PNL-AM15 and a sixteenth alignment pattern PNL-AM16 may be disposed.

For example, the first alignment pattern PNL-AM1, the second alignment pattern PNL-AM2, the third alignment pattern PNL-AM3, the fourth alignment pattern PNL-AM4, the fifth alignment pattern PNL-AM5, the sixth alignment pattern PNL-AM6, the seventh alignment pattern PNL-AM7, the ninth alignment pattern PNL-AM9, the tenth alignment pattern PNL-AM10, the eleventh alignment pattern PNL-AM11, the twelfth alignment pattern PNL-AM12, the thirteenth alignment pattern PNL-AM13, the fourteenth alignment pattern PNL-AM14, the fifteenth alignment pattern PNL-AM15, and the sixteenth alignment pattern PNL-AM16 may be disposed in the pad area PA.

For example, the first alignment pattern PNL-AM1, the second alignment pattern PNL-AM2, the third alignment pattern PNL-AM3, the fourth alignment pattern PNL-AM4, the fifth alignment pattern PNL-AM5, the sixth alignment pattern PNL-AM6, the seventh alignment pattern PNL-AM7, and the eighth alignment pattern PNL-AM8 may be disposed on a side (e.g., single side) of the pad area PA. For example, the ninth alignment pattern PNL-AM9, the tenth alignment pattern PNL-AM10, the eleventh alignment pattern PNL-AM11, the twelfth alignment pattern PNL-AM12, the thirteenth alignment pattern PNL-AM13, the fourteenth alignment pattern PNL-AM14, the fifteenth alignment pattern PNL-AM15, and the sixteenth alignment pattern PNL-AM16 may be disposed on another side of the pad area PA. Another side of the pad area PA may be spaced apart from the side of the pad area PA in the first direction DR1.

For example, the first alignment pattern PNL-AM1 may be disposed below the first substrate pad PNL-P1 in a plan view. For example, the first alignment pattern PNL-AM1 may be disposed adjacent to the first substrate pad PNL-P1 in the second direction DR2.

For example, the second alignment pattern PNL-AM2 may be disposed below the first substrate pad PNL-P1 in a plan view. For example, the second alignment pattern PNL-AM2 may be disposed adjacent to the first substrate pad PNL-P1 in the second direction DR2. The second alignment pattern PNL-AM2 may be spaced apart from the first alignment pattern PNL-AM1 in the first direction DR1. For example, the second alignment pattern PNL-AM2 may be spaced apart from the first alignment pattern PNL-AM1 in a plan view with a first film pad COF-P1 to be described later interposed therebetween.

For example, the third alignment pattern PNL-AM3 may be disposed below the second substrate pad PNL-P2 in a plan view. For example, the third alignment pattern PNL-AM3 may be disposed adjacent to the second substrate pad PNL-P2 in the second direction DR2.

For example, the fourth alignment pattern PNL-AM4 may be disposed below the second substrate pad PNL-P2 in a plan view. For example, the fourth alignment pattern PNL-AM4 may be disposed adjacent to the second substrate pad PNL-P2 in the second direction DR2. The fourth alignment pattern PNL-AM4 may be spaced apart from the third alignment pattern PNL-AM3 in the first direction DR1. For example, the fourth alignment pattern PNL-AM4 may be spaced apart from the third alignment pattern PNL-AM3 in a plan view with a second film pad COF-P2 to be described later interposed therebetween.

For example, the fifth alignment pattern PNL-AM5 may be disposed below the third substrate pad PNL-P3 in a plan view. For example, the fifth alignment pattern PNL-AM5 may be disposed adjacent to the third substrate pad PNL-P3 in the second direction DR2.

For example, the sixth alignment pattern PNL-AM6 may be disposed below the third substrate pad PNL-P3 in a plan view. For example, the sixth alignment pattern PNL-AM6 may be disposed adjacent to the third substrate pad PNL-P3 in the second direction DR2. The sixth alignment pattern PNL-AM6 may be spaced apart from the fifth alignment pattern PNL-AM5 in the first direction DR1. For example, the sixth alignment pattern PNL-AM6 may be spaced apart from the fifth alignment pattern PNL-AM5 in a plan view with a third film pad COF-P3 to be described later interposed therebetween.

For example, the seventh alignment pattern PNL-AM7 may be disposed below the fourth substrate pad PNL-P4 in a plan view. For example, the seventh alignment pattern PNL-AM7 may be disposed adjacent to the fourth substrate pad PNL-P4 in the second direction DR2.

For example, the eighth alignment pattern PNL-AM8 may be disposed below the fourth substrate pad PNL-P4 in a plan view. For example, the eighth alignment pattern PNL-AM8 may be disposed adjacent to the fourth substrate pad PNL-P4 in the second direction DR2. The eighth alignment pattern PNL-AM8 may be spaced apart from the seventh alignment pattern PNL-AM7 in the first direction DR1. For example, the eighth alignment pattern PNL-AM8 may be spaced apart from the seventh alignment pattern PNL-AM7 in a plan view with a fourth film pad COF-P4 to be described later interposed therebetween.

For example, the ninth alignment pattern PNL-AM9 may be disposed below the fifth substrate pad PNL-P5 in a plan view. For example, the ninth alignment pattern PNL-AM9 may be disposed adjacent to the fifth substrate pad PNL-P5 in the second direction DR2.

For example, the tenth alignment pattern PNL-AM10 may be disposed below the fifth substrate pad PNL-P5 in a plan view. For example, the tenth alignment pattern PNL-AM10 may be disposed adjacent to the fifth substrate pad PNL-P5 in the second direction DR2. The tenth alignment pattern PNL-AM10 may be spaced apart from the ninth alignment pattern PNL-AM9 in the direction opposite to the first direction DR1. For example, the tenth alignment pattern PNL-AM10 may be spaced apart from the ninth alignment pattern PNL-AM9 in a plan view with a fifth film pad COF-P5 to be described later interposed therebetween.

For example, the eleventh alignment pattern PNL-AM11 may be disposed below the sixth substrate pad PNL-P6 in a plan view. For example, the eleventh alignment pattern PNL-AM11 may be disposed adjacent to the sixth substrate pad PNL-P6 in the second direction DR2.

For example, the twelfth alignment pattern PNL-AM12 may be disposed below the sixth substrate pad PNL-P6 in a plan view. For example, the twelfth alignment pattern PNL-AM12 may be disposed adjacent to the sixth substrate pad PNL-P6 in the second direction DR2. The twelfth alignment pattern PNL-AM12 may be spaced apart from the eleventh alignment pattern PNL-AM11 in the direction opposite to the first direction DR1. For example, the twelfth alignment pattern PNL-AM12 may be spaced apart from the eleventh alignment pattern PNL-AM11 in a plan view with a sixth film pad COF-P6 to be described later interposed therebetween.

For example, the thirteenth alignment pattern PNL-AM13 may be disposed below the seventh substrate pad PNL-P7 in a plan view. For example, the thirteenth alignment pattern PNL-AM13 may be disposed adjacent to the seventh substrate pad PNL-P7 in the second direction DR2.

For example, the fourteenth alignment pattern PNL-AM14 may be disposed below the seventh substrate pad PNL-P7 in a plan view. For example, the fourteenth alignment pattern PNL-AM14 may be disposed adjacent to the seventh substrate pad PNL-P7 in the second direction DR2. The fourteenth alignment pattern PNL-AM14 may be spaced apart from the thirteenth alignment pattern PNL-AM13 in the direction opposite to the first direction DR1. For example, the fourteenth alignment pattern PNL-AM14 may be spaced apart from the thirteenth alignment pattern PNL-AM13 in a plan view with a seventh film pad COF-P7 to be described later interposed therebetween.

For example, the fifteenth alignment pattern PNL-AM15 may be disposed below the eighth substrate pad PNL-P8 in a plan view. For example, the fifteenth alignment pattern PNL-AM15 may be disposed adjacent to the eighth substrate pad PNL-P8 in the second direction DR2.

For example, the sixteenth alignment pattern PNL-AM16 may be disposed below the eighth substrate pad PNL-P8 in a plan view. For example, the sixteenth alignment pattern PNL-AM16 may be disposed adjacent to the eighth substrate pad PNL-P8 in the second direction DR2. The sixteenth alignment pattern PNL-AM16 may be spaced apart from the fifteenth alignment pattern PNL-AM15 in the direction opposite to the first direction DR1. For example, the sixteenth alignment pattern PNL-AM16 may be spaced apart from the fifteenth alignment pattern PNL-AM15 in a plan view with an eighth film pad COF-P8 to be described later interposed therebetween.

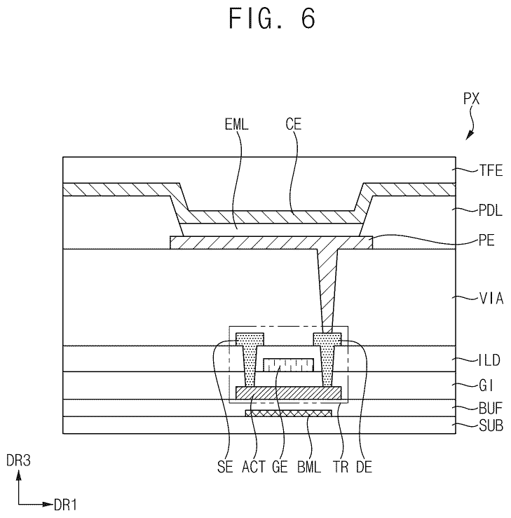

The first substrate pad PNL-P1, the second substrate pad PNL-P2, the third substrate pad PNL-P3, the fourth substrate pad PNL-P4, the fifth substrate pad PNL-P5, the sixth substrate pad PNL-P6, the seventh substrate pad PNL-P7, and the eighth substrate pad PNL-P8 may be disposed on a substantially same layer as a source electrode SE and a drain electrode DE of FIG. 6, and may include a substantially same material as the source electrode SE and the drain electrode DE of FIG. 6.

However, the disclosure is not limited thereto, and the first substrate pad PNL-P1, the second substrate pad PNL-P2, the third substrate pad PNL-P3, the fourth substrate pad PNL-P4, the fifth substrate pad PNL-P5, the sixth substrate pad PNL-P6, the seventh substrate pad PNL-P7, and the eighth substrate pad PNL-P8 may be disposed on a substantially same layer as a lower metal layer BML of FIG. 6, and may include a substantially same material as the lower metal layer BML of FIG. 6.

The first alignment pattern PNL-AM1, the second alignment pattern PNL-AM2, the third alignment pattern PNL-AM3, the fourth alignment pattern PNL-AM4, the fifth alignment pattern PNL-AM5, the sixth alignment pattern PNL-AM6, the seventh alignment pattern PNL-AM7, the eighth alignment pattern PNL-AM8, the ninth alignment pattern PNL-AM9, the tenth alignment pattern PNL-AM10, the eleventh alignment pattern PNL-AM11, the twelfth alignment pattern PNL-AM12, the thirteenth alignment pattern PNL-AM13, the fourteenth alignment pattern PNL-AM14, the fifteenth alignment pattern PNL-AM15, and the sixteenth alignment pattern PNL-AM16 may be disposed on a substantially same layer as the first substrate pad PNL-P1, and may include a substantially same material as the first substrate pad PNL-P1.

However, the disclosure is not limited thereto, and the first alignment pattern PNL-AM1, the second alignment pattern PNL-AM2, the third alignment pattern PNL-AM3, the fourth alignment pattern PNL-AM4, the fifth alignment pattern PNL-AM5, the sixth alignment pattern PNL-AM6, the seventh alignment pattern PNL-AM7, the eighth alignment pattern PNL-AM8, the ninth alignment pattern PNL-AM9, the tenth alignment pattern PNL-AM10, the eleventh alignment pattern PNL-AM11, the twelfth alignment pattern PNL-AM12, the thirteenth alignment pattern PNL-AM13, the fourteenth alignment pattern PNL-AM14, the fifteenth alignment pattern PNL-AM15, and the sixteenth alignment pattern PNL-AM16 may be disposed on a different layer from the first substrate pad PNL-P1, and may include a different material from the first substrate pad PNL-P1.

For example, the first substrate pad PNL-P1 may be disposed on a substantially same layer as the source electrode SE and the drain electrode DE of FIG. 6, and may include a substantially same material as the source electrode SE and the drain electrode DE of FIG. 6, and the first alignment pattern PNL-AM1, the second alignment pattern PNL-AM2, the third alignment pattern PNL-AM3, the fourth alignment pattern PNL-AM4, the fifth alignment pattern PNL-AM5, the sixth alignment pattern PNL-AM6, the seventh alignment pattern PNL-AM7, the eighth alignment pattern PNL-AM8, the ninth alignment pattern PNL-AM9, the tenth alignment pattern PNL-AM10, the eleventh alignment pattern PNL-AM11, the twelfth alignment pattern PNL-AM12, the thirteenth alignment pattern PNL-AM13, the fourteenth alignment pattern PNL-AM14, the fifteenth alignment pattern PNL-AM15, and the sixteenth alignment pattern PNL-AM16 may be disposed on a substantially same layer as the lower metal layer BML of FIG. 6, and may include a substantially same material as the lower metal layer BML of FIG. 6, but the disclosure is not limited thereto.

Each of the first alignment pattern PNL-AM1, the second alignment pattern PNL-AM2, the third alignment pattern PNL-AM3, the fourth alignment pattern PNL-AM4, the fifth alignment pattern PNL-AM5, the sixth alignment pattern PNL-AM6, the seventh alignment pattern PNL-AM7, the eighth alignment pattern PNL-AM8, the ninth alignment pattern PNL-AM9, the tenth alignment pattern PNL-AM10, the eleventh alignment pattern PNL-AM11, the twelfth alignment pattern PNL-AM12, the thirteenth alignment pattern PNL-AM13, the fourteenth alignment pattern PNL-AM14, the fifteenth alignment pattern PNL-AM15, and the sixteenth alignment pattern PNL-AM16 may be a cutout portion.

For example, each of the first alignment pattern PNL-AM1, the second alignment pattern PNL-AM2, the third alignment pattern PNL-AM3, the fourth alignment pattern PNL-AM4, the fifth alignment pattern PNL-AM5, the sixth alignment pattern PNL-AM6, the seventh alignment pattern PNL-AM7, the eighth alignment pattern PNL-AM8, the ninth alignment pattern PNL-AM9, the tenth alignment pattern PNL-AM10, the eleventh alignment pattern PNL-AM11, the twelfth alignment pattern PNL-AM12, the thirteenth alignment pattern PNL-AM13, the fourteenth alignment pattern PNL-AM14, the fifteenth alignment pattern PNL-AM15, and the sixteenth alignment pattern PNL-AM16 may be a portion from which at least a portion of an insulating layer disposed on the substrate SUB is removed.

For example, each of the first alignment pattern PNL-AM1, the second alignment pattern PNL-AM2, the third alignment pattern PNL-AM3, the fourth alignment pattern PNL-AM4, the fifth alignment pattern PNL-AM5, the sixth alignment pattern PNL-AM6, the seventh alignment pattern PNL-AM7, the eighth alignment pattern PNL-AM8, the ninth alignment pattern PNL-AM9, the tenth alignment pattern PNL-AM10, the eleventh alignment pattern PNL-AM11, the twelfth alignment pattern PNL-AM12, the thirteenth alignment pattern PNL-AM13, the fourteenth alignment pattern PNL-AM14, the fifteenth alignment pattern PNL-AM15, and the sixteenth alignment pattern PNL-AM16 may be a portion from which at least a portion of an insulating layer disposed on the first substrate pad PNL-P1 is removed.

For example, each of the first alignment pattern PNL-AM1, the second alignment pattern PNL-AM2, the third alignment pattern PNL-AM3, the fourth alignment pattern PNL-AM4, the fifth alignment pattern PNL-AM5, the sixth alignment pattern PNL-AM6, the seventh alignment pattern PNL-AM7, the eighth alignment pattern PNL-AM8, the ninth alignment pattern PNL-AM9, the tenth alignment pattern PNL-AM10, the eleventh alignment pattern PNL-AM11, the twelfth alignment pattern PNL-AM12, the thirteenth alignment pattern PNL-AM13, the fourteenth alignment pattern PNL-AM14, the fifteenth alignment pattern PNL-AM15, and the sixteenth alignment pattern PNL-AM16 may be a portion from which at least a portion of a via insulating layer VIA of FIG. 6 is removed.

However, the disclosure is not limited thereto, and in an embodiment, each of the first alignment pattern PNL-AM1, the second alignment pattern PNL-AM2, the third alignment pattern PNL-AM3, the fourth alignment pattern PNL-AM4, the fifth alignment pattern PNL-AM5, the sixth alignment pattern PNL-AM6, the seventh alignment pattern PNL-AM7, the eighth alignment pattern PNL-AM8, the ninth alignment pattern PNL-AM9, the tenth alignment pattern PNL-AM10, the eleventh alignment pattern PNL-AM11, the twelfth alignment pattern PNL-AM12, the thirteenth alignment pattern PNL-AM13, the fourteenth alignment pattern PNL-AM14, the fifteenth alignment pattern PNL-AM15, and the sixteenth alignment pattern PNL-AM16 may be a portion from which the via insulating layer VIA of FIG. 6 and at least a portion of a interlayer insulating layer ILD of FIG. 6 and are removed.

The first substrate alignment mark PM1 and the second substrate alignment mark PM2 may be disposed on a substantially same layer as the first substrate pad PNL-P1, and may include a substantially same material as the first substrate pad PNL-P1. However, the disclosure is not limited thereto, and the first substrate alignment mark PM1 and the second substrate alignment mark PM2 may be disposed on different layer from the first substrate pad PNL-P1, and may include different material from the first substrate pad PNL-P1.

The chip-on-film COF may include multiple film pads. For example, the chip-on-film COF may include a first film pad COF-P1, a second film pad COF-P2, a third film pad COF-P3, a fourth film pad COF-P4, a fifth film pad COF-P5, a sixth film pad COF-P6, a seventh film pad COF-P7, and an eighth film pad COF-P8.

The first film pad COF-P1, the second film pad COF-P2, the third film pad COF-P3, the fourth film pad COF-P4, the fifth film pad COF-P5, the sixth film pad COF-P6, the seventh film pad COF-P7, and the eighth film pad COF-P8 may be electrically connected to the driving chip IC.

The first film pad COF-P1 may overlap the first substrate pad PNL-P1 in a plan view in at least a portion of the pad area PA. For example, the first film pad COF-P1 may be bonded to the first substrate pad PNL-P1 in at least a portion of the pad area PA. For example, the first film pad COF-P1 may be bonded to the first substrate pad PNL-P1 through an anisotropic conductive film (“ACF”). The first film pad COF-P1 may be disposed between the first alignment pattern PNL-AM1 and the second alignment pattern PNL-AM2 in a plan view.

The second film pad COF-P2 may overlap the second substrate pad PNL-P2 in at least a portion of the pad area PA in a plan view. For example, the second film pad COF-P2 may be bonded to the second substrate pad PNL-P2 in at least a portion of the pad area PA. For example, the second film pad COF-P2 may be bonded to the second substrate pad PNL-P2 through an anisotropic conductive film. The second film pad COF-P2 may be disposed between the third alignment pattern PNL-AM3 and the fourth alignment pattern PNL-AM4 in a plan view.

The third film pad COF-P3 may overlap the third substrate pad PNL-P3 in at least a portion of the pad area PA in a plan view. For example, the third film pad COF-P3 may be bonded to the third substrate pad PNL-P3 in at least a portion of the pad area PA. For example, the third film pad COF-P3 may be bonded to the third substrate pad PNL-P3 through an anisotropic conductive film. The third film pad COF-P3 may be disposed between the fifth alignment pattern PNL-AM5 and the sixth alignment pattern PNL-AM6 in a plan view.

The fourth film pad COF-P4 may overlap the fourth substrate pad PNL-P4 in at least a portion of the pad area PA in a plan view. For example, the fourth film pad COF-P4 may be bonded to the fourth substrate pad PNL-P4 in at least a portion of the pad area PA. For example, the fourth film pad COF-P4 may be bonded to the fourth substrate pad PNL-P4 through an anisotropic conductive film. The fourth film pad COF-P4 may be disposed between the seventh alignment pattern PNL-AM7 and the eighth alignment pattern PNL-AM8 in a plan view.

The fifth film pad COF-P5 may overlap the fifth substrate pad PNL-P5 in at least a portion of the pad area PA in a plan view. For example, the fifth film pad COF-P5 may be bonded to the fifth substrate pad PNL-P5 in at least a portion of the pad area PA. For example, the fifth film pad COF-P5 may be bonded to the fifth substrate pad PNL-P5 through an anisotropic conductive film. The fifth film pad COF-P5 may be disposed between the ninth alignment pattern PNL-AM9 and the tenth alignment pattern PNL-AM10 in a plan view.

The sixth film pad COF-P6 may overlap the sixth substrate pad PNL-P6 in at least a portion of the pad area PA in a plan view. For example, the sixth film pad COF-P6 may be bonded to the sixth substrate pad PNL-P6 in at least a portion of the pad area PA. For example, the sixth film pad COF-P6 may be bonded to the sixth substrate pad PNL-P6 through an anisotropic conductive film. The sixth film pad COF-P6 may be disposed between the eleventh and twelfth alignment patterns PNL-AM11 and PNL-AM12 in a plan view.

The seventh film pad COF-P7 may overlap the seventh substrate pad PNL-P7 in at least a portion of the pad area PA in a plan view. For example, the seventh film pad COF-P7 may be bonded to the seventh substrate pad PNL-P7 in at least a portion of the pad area PA. For example, the seventh film pad COF-P7 may be bonded to the seventh substrate pad PNL-P7 through an anisotropic conductive film. The seventh film pad COF-P7 may be disposed between the thirteenth alignment pattern PNL-AM13 and the fourteenth alignment pattern PNL-AM14 in a plan view.

The eighth film pad COF-P8 may overlap the eighth substrate pad PNL-P8 in at least a portion of the pad area PA in a plan view. For example, the eighth film pad COF-P8 may be bonded to the eighth substrate pad PNL-P8 in at least a portion of the pad area PA. For example, the eighth film pad COF-P8 may be bonded to the eighth substrate pad PNL-P8 through an anisotropic conductive film. The eighth film pad COF-P8 may be disposed between the fifteenth alignment pattern PNL-AM15 and the sixteenth alignment pattern PNL-AM16 in a plan view.

For example, each of the first film pad COF-P1, the second film pad COF-P2, the third film pad COF-P3, the fourth film pad COF-P4, the fifth film pad COF-P5, the sixth film pad COF-P6, the seventh film pad COF-P7, and the eighth film pad COF-P8 may include a metal, an alloy, a metal nitride, a conductive metal oxide, a transparent conductive material, or the like. Examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), or the like. These materials may be used alone or in combination with each other. Examples of the conductive metal oxide may include Indium tin oxide, indium zinc oxide, or the like. These materials may be used alone or in combination with each other. Examples of the metal nitride may include aluminum nitride (“AlNₓ”), tungsten nitride (“WNₓ”), chromium nitride (“CrNₓ”), or the like. These materials may be used alone or in combination with each other.

The chip-on-film COF may include a first film alignment mark CM1 and a second film alignment mark CM2. The first film alignment mark CM1 and the second film alignment mark CM2 may be disposed in the pad area PA. The first film alignment mark CM1 may be disposed adjacent to the first film pad COF-P1. For example, the first film alignment mark CM1 may be disposed adjacent to the first film pad COF-P1 in the direction opposite to the first direction DR1. The second film alignment mark CM2 may be disposed adjacent to the fifth film pad COF-P5. For example, the second film alignment mark CM2 may be disposed adjacent to the fifth film pad COF-P5 in the first direction DR1.

The first film alignment mark CM1 may define a first recess CM1-RSC in a plan view. The second film alignment mark CM2 may define a second recess CM2-RSC in a plan view.

Width W2 of the first recess CM1-RSC and width W1 of the first portion PM1-1 of the first substrate alignment mark PM1 may be substantially same. For example, the width W2 of the first recess CM1-RSC in the first direction DR1 and the width W1 of the first portion PM1-1 of the first substrate alignment mark PM1 in the first direction DR1 may be substantially same.

Width W4 of the second recess CM2-RSC and width W3 of the first portion PM2-1 of the second substrate alignment mark PM2 may be substantially same as each other. For example, the width W4 of the second recess CM2-RSC in the first direction DR1 and the width W3 of the first portion PM2-1 of the second substrate alignment mark PM2 in the first direction DR1 may be substantially same.

For example, each of the first film alignment mark CM1 and the second film alignment mark CM2 may include a metal, an alloy, a metal nitride, a conductive metal oxide, a transparent conductive material, or the like. Examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), or the like. These materials may be used alone or in combination with each other. Examples of the conductive metal oxide may include Indium tin oxide, indium zinc oxide, or the like. These materials may be used alone or in combination with each other. Examples of the metal nitride may include aluminum nitride (“AlNₓ”), tungsten nitride (“WNₓ”), chromium nitride (“CrNₓ”), or the like. These materials may be used alone or in combination with each other.

The first film alignment mark CM1 and the second film alignment mark CM2 may include a substantially same material as the first film pad COF-P1. However, the disclosure is not limited thereto, and in an embodiment, each of the first film alignment mark CM1 and the second film alignment mark CM2 may include a material different from the first film pad COF-P1.

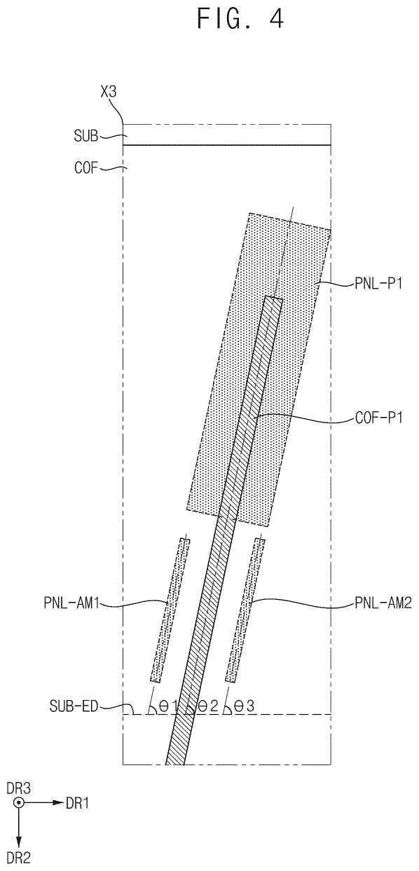

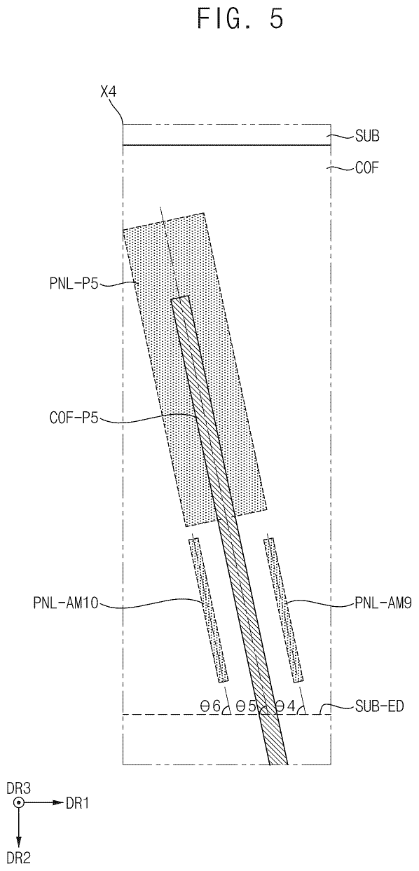

FIG. 4 is an enlarged schematic plan view of an X3 area of FIG. 2. FIG. 5 is an enlarged schematic plan view of an X4 area of FIG. 4.

Referring to FIGS. 2 and 4, the substrate SUB may include an edge SUB-ED. The edge SUB-ED of the substrate SUB may at least partially overlap the chip-on-film COF in a plan view. For example, the edge SUB-ED of the substrate SUB may extend in the first direction DR1. For example, the edge SUB-ED of the substrate SUB may be viewed as a straight line extending in the first direction DR1 in a plan view.

The first alignment pattern PNL-AM1 may have an inclined shape. For example, the first alignment pattern PNL-AM1 may form a first inclination angle θ1 with respect to the edge SUB-ED of the substrate SUB. For example, an imaginary extension line (or a center line) of the first alignment pattern PNL-AM1 may form the first inclination angle θ1 with respect to the edge SUB-ED of the substrate SUB. For example, the first inclination angle θ1 may be less than about 90 degrees.

The first substrate pad PNL-P1 may have an inclined shape. For example, the first substrate pad PNL-P1 may form a second inclination angle θ2 with respect to the edge SUB-ED of the substrate SUB. For example, an imaginary extension line (or a center line) of the first substrate pad PNL-P1 may form the second inclination angle θ2 with respect to the edge SUB-ED of the substrate SUB. For example, the second inclination angle θ2 may be less than about 90 degrees.

The first film pad COF-P1 may have an inclined shape. For example, the first film pad COF-P1 may form the second inclination angle θ2 with respect to the edge SUB-ED of the substrate SUB. For example, an imaginary extension line (or a center line) of the first film pad COF-P1 may form the second inclination angle θ2 with respect to the edge SUB-ED of the substrate SUB. For example, the second inclination angle θ2 may be less than about 90 degrees.

For example, the imaginary extension line of the first substrate pad PNL-P1 and the imaginary extension line of the first film pad COF-P1 may be equal to each other.

The second alignment pattern PNL-AM2 may have an inclined shape. For example, the second alignment pattern PNL-AM2 may form a third inclination angle θ3 with respect to the edge SUB-ED of the substrate SUB. For example, an imaginary extension line (or a center line) of the second alignment pattern PNL-AM2 may form the third inclination angle θ3 with respect to the edge SUB-ED of the substrate SUB. For example, the third inclination angle θ3 may be less than about 90 degrees.

The first inclination angle θ1 and the second inclination angle θ2 may be substantially equal to each other. For example, a degree of inclination of the first alignment pattern PNL-AM1 and a degree of inclination of the first substrate pad PNL-P1 may be substantially equal to each other. For example, the degree of inclination of the first alignment pattern PNL-AM1 and a degree of inclination of the first film pad COF-P1 may be substantially equal to each other. However, the disclosure is not limited thereto, and the first inclination angle θ1 and the second inclination angle θ2 may be different from each other.

The second inclination angle θ2 and the third inclination angle θ3 may be substantially equal to each other. For example, the degree of inclination of the first substrate pad PNL-P1 and a degree of inclination of the second alignment pattern PNL-AM2 may be substantially equal to each other. For example, the degree of inclination of the first film pad COF-P1 and the degree of inclination of the second alignment pattern PNL-AM2 may be substantially equal to each other. However, the disclosure is not limited thereto, and the second inclination angle θ2 and the third inclination angle θ3 may be different from each other.

The first substrate pad PNL-P1, the first film pad COF-P1, the first alignment pattern PNL-AM1, and the second alignment pattern PNL-AM2 have been described with reference to FIG. 4, but the disclosure is not limited thereto. For example, the second substrate pad PNL-P2, the third substrate pad PNL-P3, and the fourth substrate pad PNL-P4 may have substantially same shape as the first substrate pad PNL-P1. For example, the second film pad COF-P2, the third film pad COF-P3, and the fourth film pad COF-P4 may have substantially same shape as the first film pad COF-P1. For example, the third alignment pattern PNL-AM3, the fifth alignment pattern PNL-AM5, and the seventh alignment pattern PNL-AM7 may have substantially same shape as the first alignment pattern PNL-AM1. For example, the fourth alignment pattern PNL-AM4, the sixth alignment pattern PNL-AM6, and the eighth alignment pattern PNL-AM8 may have substantially same shape as the second alignment pattern PNL-AM2.

Referring to FIG. 3, an inclination direction of the fifth substrate pad PNL-P5 may be opposite to an inclination direction of the first substrate pad (e.g., the first substrate pad PNL-P1 of FIG. 2). For example, the fifth substrate pad PNL-P5 may be mirror-symmetric with the first substrate pad with respect to an imaginary line passing through center of the substrate SUB and extending in the second direction DR2.

An inclination direction of the sixth substrate pad PNL-P6 may be opposite to an inclination direction of the second substrate pad (e.g., the second substrate pad PNL-P2 of FIG. 2). For example, the sixth substrate pad PNL-P6 may be mirror-symmetric with the second substrate pad with respect to an imaginary line passing through the center of the substrate SUB and extending in the second direction DR2.

An inclination direction of the seventh substrate pad PNL-P7 may be opposite to an inclination direction of the third substrate pad (e.g., the third substrate pad PNL-P3 of FIG. 2). For example, the seventh substrate pad PNL-P7 may be mirror-symmetric with the third substrate pad with respect to an imaginary line passing through the center of the substrate SUB and extending in the second direction DR2.

An inclination direction of the eighth substrate pad PNL-P8 may be opposite to an inclination direction of the fourth substrate pad (e.g., the fourth substrate pad PNL-P4 of FIG. 2). For example, the eighth substrate pad PNL-P8 may be mirror-symmetric with the fourth substrate pad with respect to an imaginary line passing through the center of the substrate SUB and extending in the second direction DR2.

An inclination direction of the fifth film pad COF-P5 may be opposite to an inclination of the first film pad (e.g., the first film pad COF-P1 of FIG. 2). For example, the fifth film pad COF-P5 may be mirror-symmetric with the first film pad with respect to an imaginary line passing through the center of the substrate SUB and extending in the second direction DR2.

An inclination direction of the sixth film pad COF-P6 may be opposite to an inclination direction of the second film pad (e.g., the second film pad COF-P2 of FIG. 2). For example, the sixth film pad COF-P6 may be mirror-symmetric with the second film pad with respect to an imaginary line passing through the center of the substrate SUB and extending in the second direction DR2.

An inclination direction of the seventh film pad COF-P7 may be opposite to an inclination direction of the third film pad (e.g., the third film pad COF-P3 of FIG. 2). For example, the seventh film pad COF-P7 may be mirror-symmetrical with the third film pad with respect to an imaginary line passing through the center of the substrate SUB and extending in the second direction DR2.

An inclination direction of the eighth film pad COF-P8 may be opposite to an inclination direction of the fourth film pad (e.g., the fourth film pad COF-P4 of FIG. 2). For example, the eighth film pad COF-P8 may be mirror-symmetric with the fourth film pad with respect to an imaginary line passing through the center of the substrate SUB and extending in the second direction DR2.

An inclination direction of the ninth alignment pattern PNL-AM9 may be opposite to an inclination direction of the first alignment pattern (e.g., the first alignment pattern PNL-AM1 of FIG. 2). For example, the ninth alignment pattern PNL-AM9 may be mirror-symmetrical with the first alignment pattern with respect to an imaginary line passing through the center of the substrate SUB and extending in the second direction DR2.

An inclination direction of the tenth alignment pattern PNL-AM10 may be opposite to an inclination direction of the second alignment pattern (e.g., the second alignment pattern PNL-AM2 of FIG. 2). For example, the tenth alignment pattern PNL-AM10 may be mirror-symmetrical with the second alignment pattern with respect to an imaginary line passing through the center of the substrate SUB and extending in the second direction DR2.

An inclination direction of the eleventh alignment pattern PNL-AM11 may be opposite to an inclination direction of the third alignment pattern (e.g., the third alignment pattern PNL-AM3 of FIG. 2). For example, the eleventh alignment pattern PNL-AM11 may be mirror-symmetrical with the third alignment pattern with respect to an imaginary line passing through the center of the substrate SUB and extending in the second direction DR2.

An inclination direction of the twelfth alignment pattern PNL-AM12 may be opposite to an inclination direction of the fourth alignment pattern (e.g., the fourth alignment pattern PNL-AM4 of FIG. 2). For example, the twelfth alignment pattern PNL-AM12 may be mirror-symmetrical with the fourth alignment pattern with respect to an imaginary line passing through the center of the substrate SUB and extending in the second direction DR2.

An inclination direction of the thirteenth alignment pattern PNL-AM13 may be opposite to an inclination direction of the fifth alignment pattern (e.g., the fifth alignment pattern PNL-AM5 of FIG. 2). For example, the thirteenth alignment pattern PNL-AM13 may be mirror-symmetric with the fifth alignment pattern with respect to an imaginary line passing through the center of the substrate SUB and extending in the second direction DR2.

An inclination direction of the fourteenth alignment pattern PNL-AM14 may be opposite to an inclination direction of the sixth alignment pattern (e.g., the sixth alignment pattern PNL-AM6 of FIG. 2). For example, the fourteenth alignment pattern PNL-AM14 may be mirror-symmetric with the sixth alignment pattern with respect to an imaginary line passing through the center of the substrate SUB and extending in the second direction DR2.

An inclination direction of the fifteenth alignment pattern PNL-AM15 may be opposite to an inclination direction of the seventh alignment pattern (e.g., the seventh alignment pattern PNL-AM7 of FIG. 2). For example, the fifteenth alignment pattern PNL-AM15 may be mirror-symmetric with the seventh alignment pattern with respect to an imaginary line passing through the center of the substrate SUB and extending in the second direction DR2.

An inclination direction of the sixteenth alignment pattern PNL-AM16 may be opposite to an inclination direction of the eighth alignment pattern (e.g., the eighth alignment pattern PNL-AM8 of FIG. 2). For example, the sixteenth alignment pattern PNL-AM16 may be mirror-symmetric with the eighth alignment pattern with respect to an imaginary line passing through the center of the substrate SUB and extending in the second direction DR2.

Referring further to FIG. 5, the ninth alignment pattern PNL-AM9 may have an inclined shape. For example, the ninth alignment pattern PNL-AM9 may form a fourth inclination angle θ4 with respect to the edge SUB-ED of the substrate SUB. For example, an imaginary extension line (or a center line) of the ninth alignment pattern PNL-AM9 may form the fourth inclination angle θ4 with respect to the edge SUB-ED of the substrate SUB. For example, the fourth inclination angle θ4 may be less than about 90 degrees.

The fifth substrate pad PNL-P5 may have an inclined shape. For example, the fifth substrate pad PNL-P5 may form a fifth inclination angle θ5 with respect to the edge SUB-ED of the substrate SUB. For example, an imaginary extension line (or a center line) of the fifth substrate pad PNL-P5 may form the fifth inclination angle θ5 with respect to the edge SUB-ED of the substrate SUB. For example, the fifth inclination angle θ5 may be less than about 90 degrees.

The fifth film pad COF-P5 may have an inclined shape. For example, the fifth film pad COF-P5 may form a fifth inclination angle θ5 with respect to the edge SUB-ED of the substrate SUB. For example, an imaginary extension line (or a center line) of the fifth film pad COF-P5 may form a fifth inclination angle θ5 with respect to the edge SUB-ED of the substrate SUB. For example, the fifth inclination angle θ5 may be less than about 90 degrees.

For example, the imaginary extension line of the fifth substrate pad PNL-P5 and the imaginary extension line of the fifth film pad COF-P5 may be equal to each other.

The tenth alignment pattern PNL-AM10 may have an inclined shape. For example, the tenth alignment pattern PNL-AM10 may form a sixth inclination angle θ6 with respect to the edge SUB-ED of the substrate SUB. For example, an imaginary extension line (or a center line) of the tenth alignment pattern PNL-AM10 may form the sixth inclination angle θ6 with respect to the edge SUB-ED of the substrate SUB. For example, the sixth inclination angle θ6 may be less than about 90 degrees.

The fourth inclination angle θ4 and the fifth inclination angle θ5 may be substantially equal to each other. For example, a degree of inclination of the ninth alignment pattern PNL-AM9 and a degree of inclination of the fifth substrate pad PNL-P5 may be substantially equal to each other. For example, the degree of inclination of the ninth alignment pattern PNL-AM9 and a degree of inclination of the fifth film pad COF-P5 may be substantially equal to each other. However, the disclosure is not limited thereto, and the fourth inclination angle θ4 and the fifth inclination angle θ5 may be different from each other.

The fifth inclination angle θ5 and the sixth inclination angle θ6 may be substantially equal to each other. For example, a degree of inclination of the fifth substrate pad PNL-P5 and a degree of inclination of the tenth alignment pattern PNL-AM10 may be substantially equal to each other. For example, the degree of inclination of the fifth film pad COF-P5 and a degree of inclination of the tenth alignment pattern PNL-AM10 may be substantially equal to each other. However, the disclosure is not limited thereto, and the fifth inclination angle θ5 and the sixth inclination angle θ6 may be different from each other.

The fifth substrate pad PNL-P5, the fifth film pad COF-P5, the ninth alignment pattern PNL-AM9, and the tenth alignment pattern PNL-AM10 have been described with reference to FIG. 5, but the disclosure is not limited thereto.

For example, the sixth substrate pad PNL-P6, the seventh substrate pad PNL-P7, and the eighth substrate pad PNL-P8 may have substantially same shape as the fifth substrate pad PNL-P5. For example, the sixth film pad COF-P6, the seventh film pad COF-P7, and the eighth film pad COF-P8 may have substantially same shape as the fifth film pad COF-P5. For example, the eleventh alignment pattern PNL-AM11, the thirteenth alignment pattern PNL-AM13, and the fifteenth alignment pattern PNL-AM15 may have substantially same shape as the ninth alignment pattern PNL-AM9. For example, the twelfth alignment pattern PNL-AM12, the fourteenth alignment pattern PNL-AM14, and the sixteenth alignment pattern PNL-AM16 may have substantially same shape as the tenth alignment pattern PNL-AM10.

FIG. 6 is a schematic cross-sectional view illustrating pixels included in the display device of FIG. 1.

Referring to FIG. 6, the pixel PX may include a substrate SUB, a buffer layer BUF, a lower metal layer BML, a gate insulating layer GI, an interlayer insulating layer ILD, a via insulating layer VIA, an active layer ACT, a source electrode SE, a gate electrode GE, a drain electrode DE, a pixel electrode PE, a pixel defining layer PDL, a light emitting layer EML, a common electrode CE, and an encapsulation layer TFE.

The transistor TR may include the active layer ACT, the source electrode SE, the gate electrode GE, and the drain electrode DE.

The substrate SUB may include a transparent material or an opaque material. The substrate SUB may be formed of a transparent resin substrate. Example of the transparent resin substrate may include a polyimide substrate. For example, the polyimide substrate may include a first organic layer, a first barrier layer, a second organic layer, and the like.

In another example, the substrate SUB may include a quartz substrate (e.g., a synthetic quartz substrate, a fluorine-doped quartz substrate), a calcium fluoride substrate, a sodalime glass substrate, a non-alkali glass substrate, or the like. These materials may be used alone or in combination with each other.

The lower metal layer BML may be disposed on the substrate SUB. The lower metal layer BML may include a metal, an alloy, a metal nitride, a conductive metal oxide, a transparent conductive material, or the like. Examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), or the like. These materials may be used alone or in combination with each other. Examples of the conductive metal oxide may include Indium tin oxide, indium zinc oxide, or the like. These materials may be used alone or in combination with each other. Examples of the metal nitride may include aluminum nitride (“AlNₓ”), tungsten nitride (“WNₓ”), chromium nitride (“CrNₓ”), or the like. These materials may be used alone or in combination with each other.

The buffer layer BUF may be disposed on the substrate SUB. The buffer layer BUF may cover the lower metal layer BML. The buffer layer BUF may prevent metal atoms or impurities from diffusing from the substrate SUB to the transistor TR. The buffer layer BUF can improve flatness of a surface of the substrate SUB in case that the surface of the substrate SUB is not uniform.

For example, the buffer layer BUF may include an inorganic material such as silicon oxide, silicon nitride, silicon oxynitride, or the like. These materials may be used alone or in combination with each other.

The active layer ACT may be disposed on the buffer layer BUF. The active layer ACT may include an inorganic semiconductor (e.g., amorphous silicon, polysilicon, a metal oxide semiconductor,), an organic semiconductor, or the like. These materials may be used alone or in combination with each other. The active layer ACT may include a source area, a drain area, and a channel area disposed between the source area and the drain area.

The metal oxide semiconductor may include a binary compound (“ABₓ”), a ternary compound (“ABₓC_{y}”), a quaternary compound (“ABₓC_{y}D_{z}”), or the like including indium (“In”), zinc (“Zn”), gallium (“Ga”), tin (“Sn”), titanium (“Ti”), aluminum (“Al”), hafnium (“Hf”), zirconium (“Zr”), magnesium (“Mg”), or the like. These materials may be used alone or in combination with each other. For example, the metal oxide semiconductor may include zinc oxide (“ZnOₓ”), gallium oxide (“GaOₓ”), tin oxide (“SnOₓ”), indium oxide (“InOₓ”), indium gallium oxide (“IGO”), indium zinc oxide (“IZO”), indium tin oxide (“ITO”), indium zinc tin oxide (“IZTO”), and indium gallium zinc oxide (“IGZO”). These materials may be used alone or in combination with each other.

The gate insulating layer GI may be disposed on the buffer layer BUF. The gate insulating layer GI may cover (e.g., sufficiently cover) the active layer ACT. For example, the gate insulating layer GI may cover the active layer ACT and may be disposed along a profile of the active layer ACT.

For example, the gate insulating layer GI may include inorganic materials such as silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), or the like. These materials may be used alone or in combination with each other.

The gate electrode GE may be disposed on the gate insulating layer GI. The gate electrode GE may overlap the channel area of the active layer ACT in the third direction DR3.

The gate electrode GE may include a metal, an alloy, a metal nitride, a conductive metal oxide, a transparent conductive material, or the like. Examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), or the like. These materials may be used alone or in combination with each other. Examples of the conductive metal oxide may include Indium tin oxide, indium zinc oxide, or the like. These materials may be used alone or in combination with each other. Examples of the metal nitride may include aluminum nitride (“AlNₓ”), tungsten nitride (“WNₓ”), chromium nitride (“CrNₓ”), or the like. These materials may be used alone or in combination with each other.

The interlayer insulating layer ILD may be disposed on the gate insulating layer GI. The interlayer insulating layer ILD may cover (e.g., sufficiently cover) the gate electrode GE. For example, the interlayer insulating layer ILD may cover the gate electrode GE and may be disposed along a profile of the gate electrode GE.

For example, the interlayer insulating layer ILD may include inorganic materials such as silicon oxide, silicon nitride, silicon carbide, silicon oxynitride, silicon oxycarbide, or the like. These materials may be used alone or in combination with each other.

The source electrode SE may be disposed on the interlayer insulating layer ILD. The source electrode SE may be electrically connected to the source area of the active layer ACT through a first contact hole defining through the gate insulating layer GI and the interlayer insulating layer ILD.

The drain electrode DE may be disposed on the interlayer insulating layer ILD. The drain electrode DE may be electrically connected to the drain area of the active layer ACT through a second contact hole defining through the gate insulating layer GI and the interlayer insulating layer ILD.

For example, the source electrode SE may include a metal, an alloy, a metal nitride, a conductive metal oxide, a transparent conductive material, or the like. These materials may be used alone or in combination with each other. The drain electrode DE and the source electrode SE may be formed through a same process and may include a same material to each other.

The via insulating layer VIA may be disposed on the interlayer insulating layer ILD. The via insulating layer VIA may cover (e.g., sufficiently cover) the source electrode SE and the drain electrode DE. The via insulating layer VIA may include organic material. For example, the via insulating layer VIA may include organic materials such as phenolic resin, acrylic resin, polyimide resin, polyamide resin, siloxane resin, epoxy resin, or the like. These materials may be used alone or in combination with each other.

The pixel electrode PE may be disposed on the via insulating layer VIA. The pixel electrode PE may be electrically connected to the drain electrode DE through a contact hole penetrating the via insulating layer VIA.

The pixel electrode PE may include a metal, an alloy, a metal nitride, a conductive metal oxide, a transparent conductive material, or the like. These materials be used alone or in combination with each other. The pixel electrode PE may have a stacked structure including ITO/Ag/ITO. For example, the pixel electrode PE may operate as an anode.

The pixel defining layer PDL may be disposed on the via insulating layer VIA. The pixel defining layer PDL may cover side portions of the pixel electrode PE. An opening exposing a portion of the upper surface of the pixel electrode PE may be defined in the pixel defining layer PDL.

For example, the pixel defining layer PDL may include an inorganic material or an organic material. The pixel defining layer PDL may include an organic material such as an epoxy resin, a siloxane resin, or the like. These materials may be used alone or in combination with each other. In another embodiment, the pixel defining layer PDL may further include a light blocking material containing a black pigment, a black dye, or the like.

The light emitting layer EML may be disposed on the pixel electrode PE. The light emitting layer EML may include an organic material that emits light of a predetermined color. For example, the light emitting layer EML may include an organic material that emits red light. However, the disclosure is not limited thereto, and the light emitting layer EML may emit light of a different color from red light.

The common electrode CE may be disposed on the light emitting layer EML and the pixel defining layer PDL. The common electrode CE may include a metal, an alloy, a metal nitride, a conductive metal oxide, a transparent conductive material, or the like. These materials may be used alone or in combination with each other. The common electrode CE may operate as a cathode.

The encapsulation layer TFE may be disposed on the common electrode CE. The encapsulation layer TFE may prevent impurities and moisture from penetrating into the pixel electrode PE, the light emitting layer EML, and the common electrode CE from the outside. The encapsulation layer TFE may include at least one inorganic layer and at least one organic layer.

For example, the inorganic layer may include silicon oxide, silicon nitride, silicon oxynitride, or the like. These materials may be used alone or in combination with each other. The organic layer may include a polymer cured product such as polyacrylate.

Although an embodiment of the pixel PX has been described with reference to FIG. 6, the pixel PX is not limited to the structure illustrated in FIG. 6. For example, the pixel PX may include all structures that receive an electrical signal and emit light having a luminance corresponding to the intensity of the electrical signal.

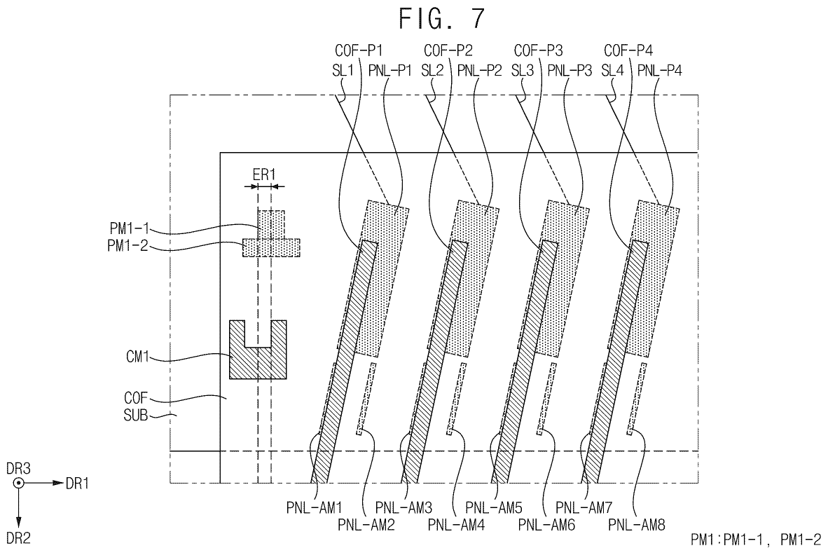

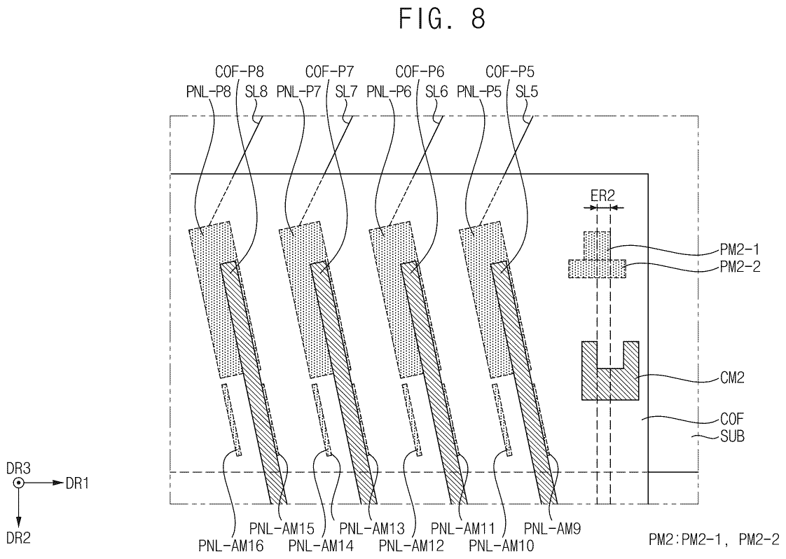

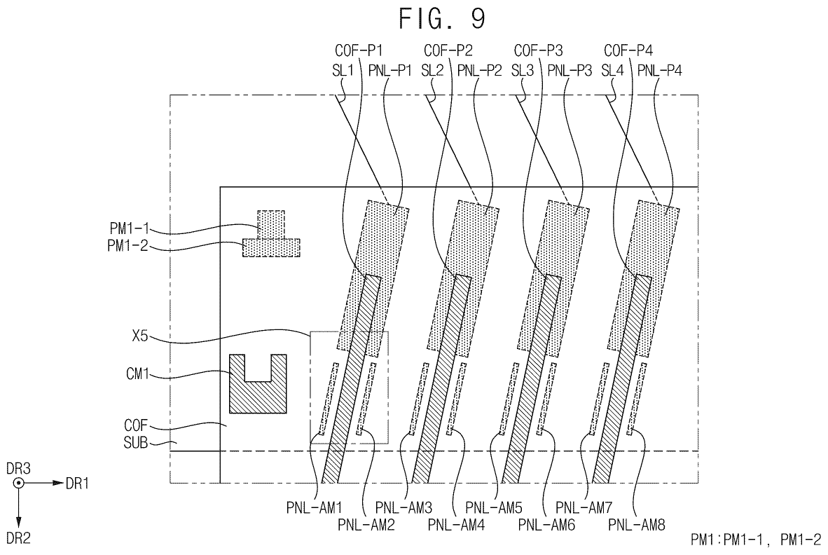

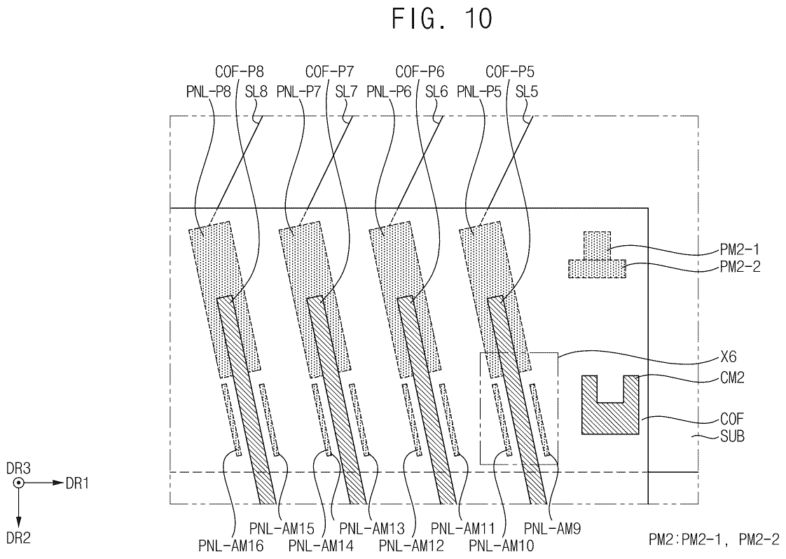

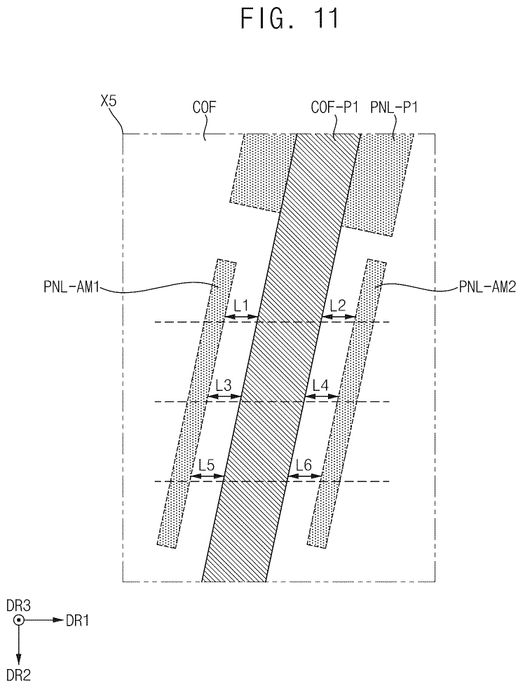

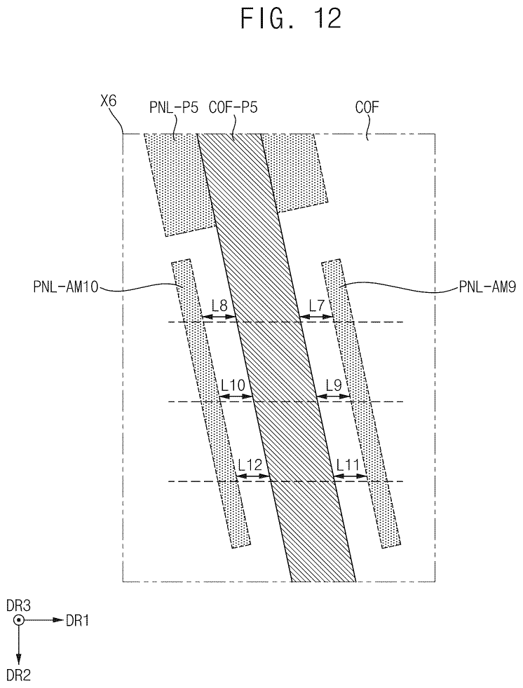

FIGS. 7 and 8 are schematic plan views illustrating a case in which a chip-on-film included in the display device of FIG. 1 is expanded. FIGS. 9 and 10 are schematic plan views illustrating the chip-on-film disposed at an adjusted position. FIG. 11 is an enlarged schematic plan view illustrating an X5 area of FIG. 9. FIG. 12 is an enlarged schematic plan view illustrating an X6 area of FIG. 10.

FIGS. 7, 8, 9, 10, 11, and 12 are schematic plan views illustrating a method of manufacturing a display device (e.g., the display device DD of FIG. 1) by adjusting position of the chip-on-film COF in case that the chip-on-film COF is attached to the substrate SUB in the expanded position.

Referring to FIGS. 7 and 8, the chip-on-film COF may be attached to one side (or another side) of the substrate SUB in the expanded position. In case that the chip-on-film COF is expanded, width of each of multiple film pads included in the chip-on-film COF may increase. For example, width of each of the first film pad COF-P1, the second film pad COF-P2, the third film pad COF-P3, the fourth film pad COF-P4, the fifth film pad COF-P5, the sixth film pad COF-P6, the seventh film pad COF-P7, and the eighth film pad COF-P8 may increase.

In case that the chip-on-film COF is expanded, a separation distance between adjacent film pads may increase. For example, a separation distance between the first film pad COF-P1 and the second film pad COF-P2 may increase. Accordingly, in case that the chip-on-film COF is attached to one side (or another side) of the substrate SUB in the expanded position, a misalignment may occur between multiple film pads and multiple substrate pads disposed on the substrate SUB.

Whether the chip-on-film COF is expanded may be checked by checking the first substrate alignment mark PM1, the second substrate alignment mark PM2, the first film alignment mark CM1, and the second film alignment mark CM2. For example, whether the chip-on-film COF is expanded may be checked by checking relative positions of the first substrate alignment mark PM1 and the first film alignment mark CM1. Whether the chip-on-film COF is expanded may be checked by checking relative positions of the second substrate alignment mark PM2 and the second film alignment mark CM2.

In case that the chip-on-film COF is attached to a side (e.g., single side) of the substrate SUB in the expanded position, the first film alignment mark CM1 may be shifted in the direction opposite to the first direction DR1 with respect to the first substrate alignment mark PM1. For example, in case that the chip-on-film COF is expanded, as compared with case of FIG. 2, the first film alignment mark CM1 may be shifted in the direction opposite to the first direction DR1. For example, in case that the chip-on-film COF is expanded, the first film alignment mark CM1 may be shifted in the direction opposite to the first direction DR1 by a first distance ER1 with respect to the first substrate alignment mark PM1. For example, in case that the chip-on-film COF is expanded, a center line of the first film alignment mark CM1 may be shifted in the direction opposite to the first direction DR1 by the first distance ER1 with respect to a center line of the first substrate alignment mark PM1. The center line of the first substrate alignment mark PM1 may pass through a center portion of the first substrate alignment mark PM1 and extend in the second direction DR2. The center line of the first film alignment mark CM1 may pass through a center portion of the first film alignment mark CM1 and extend in the second direction DR2.

In case that the chip-on-film COF is attached to another side of the substrate SUB in the expanded position, the second film alignment mark CM2 may be shifted in the first direction DR1 with respect to the second substrate alignment mark PM2. For example, in case that the chip-on-film COF is expanded, as compared with case of FIG. 3, the second film alignment mark CM2 may be shifted in the first direction DR1. For example, in case that the chip-on-film COF is expanded, the second film alignment mark CM2 may be shifted in the first direction DR1 by a second distance ER2 with respect to the second substrate alignment mark PM2. For example, in case that the chip-on-film COF is expanded, a center line of the second film alignment mark CM2 may be shifted in the first direction DR1 by the second distance ER2 with respect to a center line of the second substrate alignment mark PM2. The center line of the second substrate alignment mark PM2 may pass through a center portion of the second substrate alignment mark PM2 and extend in the second direction DR2. The center line of the second film alignment mark CM2 may pass through a center portion of the second film alignment mark CM2 and extend in the second direction DR2.

Referring to FIGS. 9 and 10, in case that the chip-on-film COF is attached to one side (or another side) of the substrate SUB in the expanded position, position of the chip-on-film COF may be adjusted. For example, in case that the chip-on-film COF is attached to one side (or another side) of the substrate SUB in the expanded position, the chip-on-film COF may move in a direction away from the substrate SUB in order to align multiple substrate pads and multiple film pads, respectively. For example, in case that the chip-on-film COF is attached to one side (or another side) of the substrate SUB in the expanded position, the chip-on-film COF may move in the second direction DR2.

In case that the chip-on-film COF moves in the second direction DR2, the first film pad COF-P1, the second film pad COF-P2, the third film pad COF-P3, the fourth film pad COF-P4, the fifth film pad COF-P5, the sixth film pad COF-P6, the seventh film pad COF-P7, the eighth film pad COF-P8, the first film alignment mark CM1, and the second film alignment mark CM2 may be moved in the second direction DR2.

After the chip-on-film COF moves in the second direction DR2, it may be necessary to check whether multiple substrate pads and multiple film pads are aligned, respectively. For example, relative positions of the first substrate alignment mark PM1 and the first film alignment mark CM1 and relative positions of the second substrate alignment mark PM2 and the second film alignment mark CM2 may not provide information on whether multiple substrate pads and multiple film pads are aligned, respectively. This may be because the first film alignment mark CM1 and the second film alignment mark CM2 move only in the second direction DR2, so that the first distance (e.g., the first distance ER1 of FIG. 7) and the second distance (e.g., the second distance ER2 of FIG. 8) do not change. Hereinafter, a method of checking whether multiple substrate pads and multiple film pads are aligned, respectively through multiple alignment patterns disposed on the substrate SUB will be described.

Referring to FIGS. 9 and 11, a separation distance between the first film pad COF-P1 and the first alignment pattern PNL-AM1 may be measured. A separation distance between the first film pad COF-P1 and the second alignment pattern PNL-AM2 may be measured.

For example, at a first position, a first separation distance L1 between the first film pad COF-P1 and the first alignment pattern PNL-AM1 may be measured. At the first position, a second separation distance L2 between the first film pad COF-P1 and the second alignment pattern PNL-AM2 may be measured.

In case that the first separation distance L1 and the second separation distance L2 are substantially equal to each other, it may be determined that multiple substrate pads and multiple film pads are properly aligned, respectively. For example, in case that the first separation distance L1 and the second separation distance L2 are substantially equal to each other, it may be determined that the substrate SUB and the chip-on-film COF are properly aligned. For example, in case that the first separation distance L1 and the second separation distance L2 are substantially equal to each other, it may be determined that the chip-on-film COF is properly attached to a side (e.g., single side) of the substrate SUB.

If the first separation distance L1 is greater than the second separation distance L2, the chip-on-film COF may additionally move upward in the direction opposite to the second direction DR2. In case that the first separation distance L1 is less than the second separation distance L2, the chip-on-film COF may move downward in the second direction DR2.

A third separation distance L3 between the first film pad COF-P1 and the first alignment pattern PNL-AM1 may be measured at a second position. A fourth separation distance L4 between the first film pad COF-P1 and the second alignment pattern PNL-AM2 may be measured at the second position.

A fifth separation distance L5 between the first film pad COF-P1 and the first alignment pattern PNL-AM1 may be measured at a third position. A sixth separation distance L6 between the first film pad COF-P1 and the second alignment pattern PNL-AM2 may be measured at the third position.

This may be because if separation distance between the first film pad COF-P1 and the first alignment pattern PNL-AM1 and the separation distance between the first film pad COF-P1 and the second alignment pattern PNL-AM2 are measured multiple times, whether multiple substrate pads and multiple film pads are properly aligned may be more precisely measured.

Referring to FIGS. 10 and 12, a separation distance between the fifth film pad COF-P5 and the ninth alignment pattern PNL-AM9 may be measured. A separation distance between the fifth film pad COF-P5 and the tenth alignment pattern PNL-AM10 may be measured.

For example, at a fourth position, a seventh separation distance L7 between the fifth film pad COF-P5 and the ninth alignment pattern PNL-AM9 may be measured. In the fourth position, an eighth separation distance L8 between the fifth film pad COF-P5 and the tenth alignment pattern PNL-AM10 may be measured.

In case that the seventh separation distance L7 and the eighth separation distance L8 are substantially equal to each other, it may be determined that multiple substrate pads and multiple film pads are properly aligned, respectively. For example, in case that the seventh separation distance L7 and the eighth separation distance L8 are substantially equal to each other, it may be determined that the substrate SUB and the chip-on-film COF are properly aligned. For example, in case that the seventh separation distance L7 and the eighth separation distance L8 are substantially equal to each other, it may be determined that the chip-on-film COF is properly attached to another side of the substrate SUB.

If the seventh separation distance L7 is greater than the eighth separation distance L8, the chip-on-film COF may move upward in the direction opposite to the second direction DR2. In case that the seventh separation distance L7 is less than the eighth separation distance L8, the chip-on-film COF may downward move in the second direction DR2.

A ninth separation distance L9 between the fifth film pad COF-P5 and the ninth alignment pattern PNL-AM9 may be measured at a fifth position. A tenth separation distance L10 between the fifth film pad COF-P5 and the tenth alignment pattern PNL-AM10 may be measured at the fifth position.

An eleventh separation distance L11 between the fifth film pad COF-P5 and the ninth alignment pattern PNL-AM9 may be measured at a sixth position. A twelfth separation distance L12 between the fifth film pad COF-P5 and the tenth alignment pattern PNL-AM10 may be measured at the sixth position.

This may be because if the separation distance between the fifth film pad COF-P5 and the ninth alignment pattern PNL-AM9 and the separation distance between the fifth film pad COF-P5 and the tenth alignment pattern PNL-AM10 are measured multiple times, whether multiple substrate pads and multiple film pads are properly aligned, respectively may be more precisely measured.

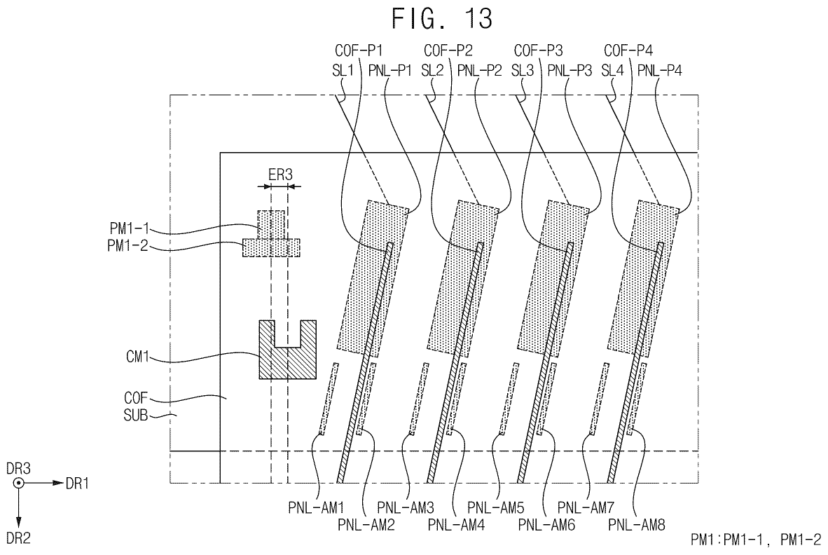

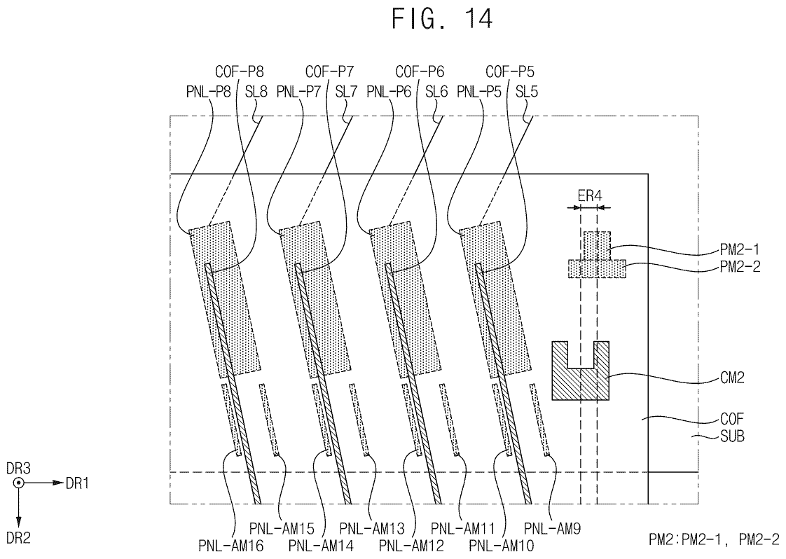

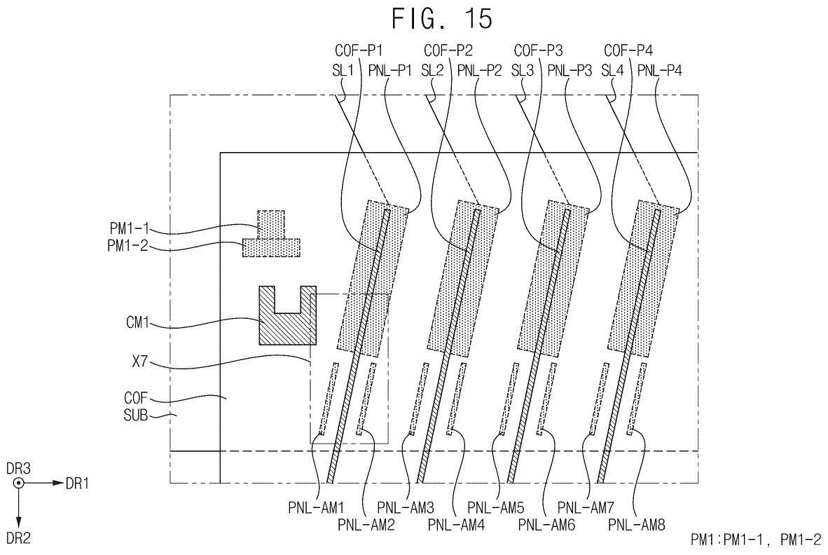

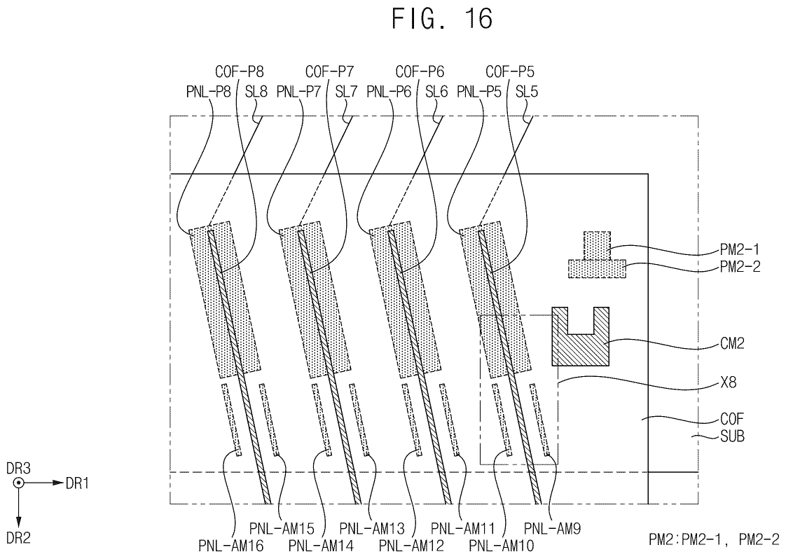

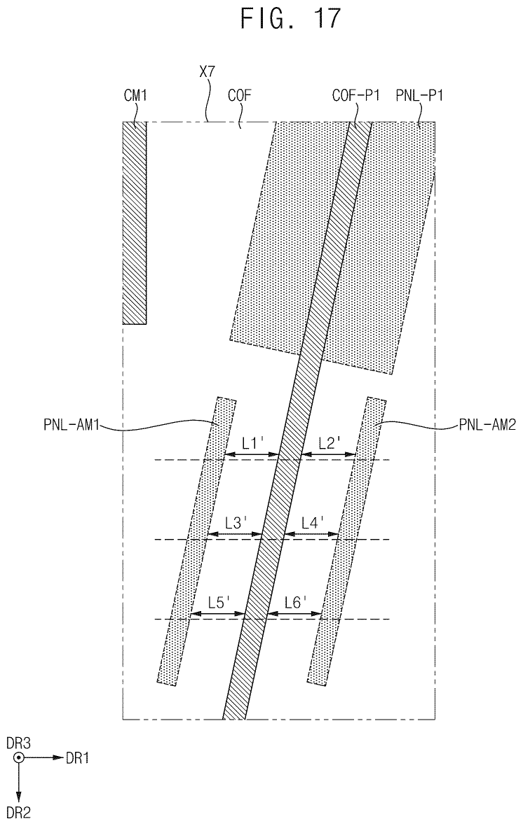

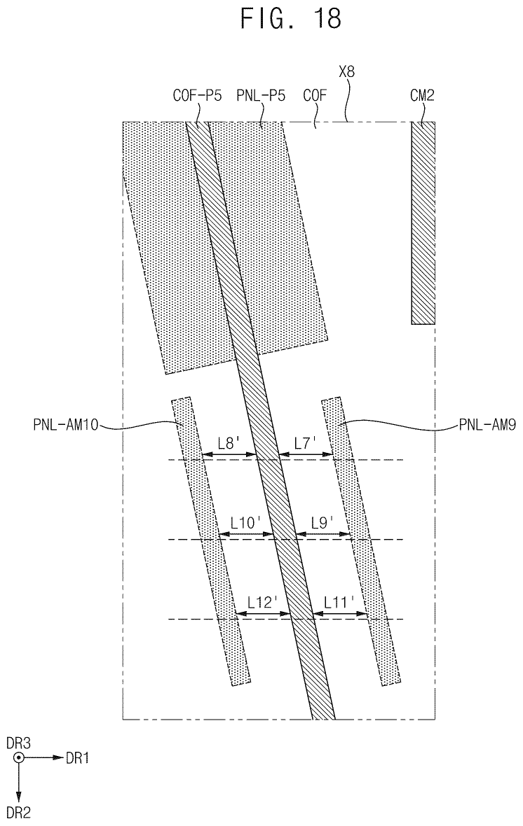

FIGS. 13 and 14 are schematic plan views illustrating a case in which the chip-on-film included in the display device of FIG. 1 is contracted. FIGS. 15 and 16 are schematic plan views illustrating the chip-on-film disposed at an adjusted position. FIG. 17 is an enlarged schematic plan view illustrating an X7 area of FIG. 15. FIG. 18 is an enlarged schematic plan view illustrating an X8 area of FIG. 16.

FIGS. 13, 14, 15, 16, 17, and 18 are schematic plan views illustrating a method of manufacturing a display device (e.g., the display device DD of FIG. 1) by adjusting position of the chip-on-film COF in case that the chip-on-film COF is attached to the substrate SUB in the contracted position.

Referring to FIGS. 13 and 14, the chip-on-film COF may be attached to one side (or another side) of the substrate SUB in the contracted position. In case that the chip-on-film COF is contracted, width of each of multiple film pads included in the chip-on-film COF may decrease. For example, width of each of the first film pad COF-P1, the second film pad COF-P2, the third film pad COF-P3, the fourth film pad COF-P4, the fifth film pad COF-P5, the sixth film pad COF-P6, the seventh film pad COF-P7, and the eighth film pad COF-P8 may decrease. In case that the chip-on-film COF is contracted, a separation distance between adjacent film pads may decrease. For example, a separation distance between the first film pad COF-P1 and the second film pad COF-P2 may decrease. Accordingly, in case that the chip-on-film COF is attached to one side (or another side) of the substrate SUB in the contracted position, a misalignment may occur between multiple film pads and the plurality of substrate pads disposed on the substrate SUB.

Whether the chip-on-film COF is contracted may be checked by checking the first substrate alignment mark PM1, the second substrate alignment mark PM2, the first film alignment mark CM1, and the second film alignment mark CM2. For example, whether the chip-on-film COF is contracted may be checked by checking relative positions of the first substrate alignment mark PM1 and the first film alignment mark CM1. Whether the chip-on-film COF is contracted may be checked by checking relative positions of the second substrate alignment mark PM2 and the second film alignment mark CM2.

In case that the chip-on-film COF is attached to one side (or another side) of the substrate SUB in the contracted position, the first film alignment mark CM1 may be shifted in the first direction DR1 with respect to the first substrate alignment mark PM1. For example, in case that the chip-on-film COF is contracted, as compared with case of FIG. 2, the first film alignment mark CM1 may be shifted in the first direction DR1. For example, in case that the chip-on-film COF is contracted, the first film alignment mark CM1 may be shifted in the first direction DR1 by a third distance ER3 with respect to the first substrate alignment mark PM1. For example, in case that the chip-on-film COF is contracted, the center line of the first film alignment mark CM1 may be shifted in the first direction DRI by the third distance ER3 with respect to the center line of the first substrate alignment mark PM1.

In case that the chip-on-film COF is attached to one side (or another side) of the substrate SUB in the contracted position, the second film alignment mark CM2 may be shifted in the direction opposite to the first direction DR1 with respect to the second substrate alignment mark PM2. For example, in case that the chip-on-film COF is contracted, as compared with case of FIG. 3, the second film alignment mark CM2 may be shifted in the direction opposite to first direction DR1. For example, in case that the chip-on-film COF is contracted, the second film alignment mark CM2 may be shifted in the direction opposite to first direction DR1 by a fourth distance ER4 with respect to the second substrate alignment mark PM2. For example, in case that the chip-on-film COF is contracted, the center line of the second film alignment mark CM2 may be shifted in the direction opposite to the first direction DR1 by the fourth distance ER4 with respect to the center line of the second substrate alignment mark PM2.

Referring to FIGS. 15 and 16, in case that the chip-on-film COF is attached to one side (or another side) of the substrate SUB in the contracted position, position of the chip-on-film COF may be adjusted. For example, in case that the chip-on-film COF is attached to another side of the substrate SUB in the contracted position, in order to align multiple substrate pads and multiple film pads, respectively, the chip-on-film COF may move so that an area in which the substrate SUB and the chip-on-film COF overlap in a plan view increases. For example, in case that the chip-on-film COF is attached to one side (or another side) of the substrate SUB in the contracted position, the chip-on-film COF may move in the direction opposite to the second direction DR2.

In case that the chip-on-film COF moves in the direction opposite to the second direction DR2, the first film pad COF-P1, the second film pad COF-P2, the third film pad COF-P3, the fourth film pad COF-P4, the fifth film pad COF-P5, the sixth film pad COF-P6, the seventh film pad COF-P7, the eighth film pad COF-P8, the first film alignment mark CM1, and the second film alignment mark CM2 may move in the direction opposite to the second direction DR2.

After the chip-on-film COF moves in the direction opposite to the second direction DR2, it may be necessary to check whether multiple substrate pads and multiple film pads are aligned, respectively. For example, relative positions of the first substrate alignment mark PM1 and the first film alignment mark CM1 and relative positions of the second substrate alignment mark PM2 and the second film alignment mark CM2 may not provide information on whether multiple substrate pads and multiple film pads are aligned, respectively. This may be because the first film alignment mark CM1 and the second film alignment mark CM2 move only in the direction opposite to the second direction DR2, so that the third distance (e.g., the third distance ER3 of FIG. 13) and the fourth distance (e.g., the fourth distance ER4 of FIG. 14) do not change. Hereinafter, a method of checking whether multiple substrate pads and multiple film pads are aligned, respectively through multiple alignment patterns will be described.

Referring to FIGS. 15 and 17, a separation distance between the first film pad COF-P1 and the first alignment pattern PNL-AM1 may be measured. A separation distance between the first film pad COF-P1 and the second alignment pattern PNL-AM2 may be measured.

For example, at a first position, a first separation distance L1′ between the first film pad COF-P1 and the first alignment pattern PNL-AM1 may be measured. At the first position, a second separation distance L2′ between the first film pad COF-P1 and the second alignment pattern PNL-AM2 may be measured.

In case that the first separation distance L1′ and the second separation distance L2′ are equal to each other, it may be determined that multiple substrate pads and multiple film pads are properly aligned, respectively. For example, in case that the first separation distance L1′ and the second separation distance L2′ are equal to each other, it may be determined that the substrate SUB and the chip-on-film COF are properly aligned. For example, in case that the first separation distance L1′ and the second separation distance L2′ are equal to each other, it may be determined that the chip-on-film COF is properly attached to a side (e.g., single side) of the substrate SUB.

If the first separation distance L1′ is greater than the second separation distance L2′, the chip-on-film COF may move upward in the direction opposite to the second direction DR2. If the first separation distance L1′ is less than the second separation distance L2′, the chip-on-film COF may downward move in the second direction DR2.

A third separation distance L3′ between the first film pad COF-P1 and the first alignment pattern PNL-AM1 may be measured at a second position. A fourth separation distance L4′ between the first film pad COF-P1 and the second alignment pattern PNL-AM2 may be measured at the second position.

A fifth separation distance L5′ between the first film pad COF-P1 and the first alignment pattern PNL-AM1 may be measured at a third position. A sixth separation distance L6′ between the first film pad COF-P1 and the second alignment pattern PNL-AM2 may be measured at the third position.

This may be because if separation distance between the first film pad COF-P1 and the first alignment pattern PNL-AM1 and the separation distance between the first film pad COF-P1 and the second alignment pattern PNL-AM2 are measured multiple times, whether multiple substrate pads and multiple film pads are properly aligned may be more precisely measured.

Referring to FIGS. 16 and 18, a separation distance between the fifth film pad COF-P5 and the ninth alignment pattern PNL-AM9 may be measured. A separation distance between the fifth film pad COF-P5 and the tenth alignment pattern PNL-AM10 may be measured.

For example, at a fourth position, a seventh separation distance L7′ between the fifth film pad COF-P5 and the ninth alignment pattern PNL-AM9 may be measured. In the fourth position, an eighth separation distance L8′ between the fifth film pad COF-P5 and the tenth alignment pattern PNL-AM10 may be measured.

In case that the seventh separation distance L7′ and the eighth separation distance L8′ are equal, it may be determined that multiple substrate pads and multiple film pads are properly aligned, respectively. For example, in case that the seventh separation distance L7′ and the eighth separation distance L8′ are equal, it may be determined that the substrate SUB and the chip-on-film COF are properly aligned. For example, in case that the seventh separation distance L7′ and the eighth separation distance L8′ are equal, it may be determined that the chip-on-film COF is properly attached to another side of the substrate SUB.

If the seventh separation distance L7′ is greater than the eighth separation distance L8′, the chip-on-film COF may upward move in the direction opposite to the second direction DR2. If the seventh separation distance L7′ is less than the eighth separation distance L8′, the chip-on-film COF may move downward in the second direction DR2.

A ninth separation distance L9′ between the fifth film pad COF-P5 and the ninth alignment pattern PNL-AM9 may be measured at a fifth position. A tenth separation distance L10′ between the fifth film pad COF-P5 and the tenth alignment pattern PNL-AM10 may be measured at the fifth position.

An eleventh separation distance L11′ between the fifth film pad COF-P5 and the ninth alignment pattern PNL-AM9 may be measured at a sixth position. A twelfth separation distance L12′ between the fifth film pad COF-P5 and the tenth alignment pattern PNL-AM10 may be measured at the sixth position.

This may be because if the separation distance between the fifth film pad COF-P5 and the ninth alignment pattern PNL-AM9 and the separation distance between the fifth film pad COF-P5 and the tenth alignment pattern PNL-AM10 are measured multiple times, whether multiple substrate pads and multiple film pads are properly aligned, respectively may be more precisely measured.

For example, as the display device (e.g., the display device DD of FIG. 1) includes multiple alignment patterns on the substrate SUB, it may be precisely determined whether the chip-on-film COF is properly attached to one side (or another side) of the substrate SUB.

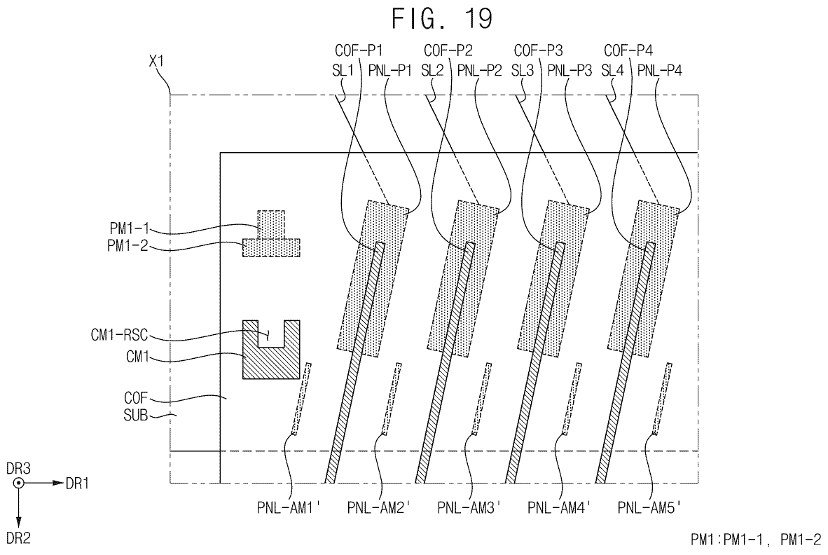

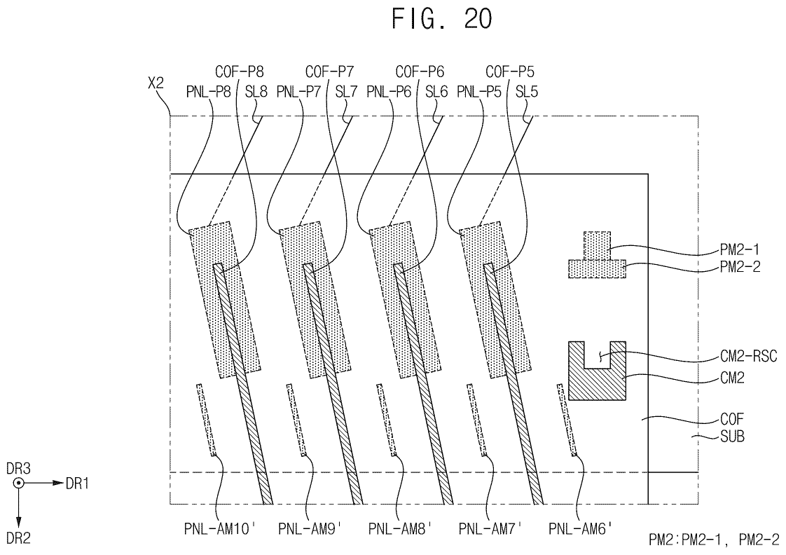

FIG. 19 is an enlarged schematic plan view illustrating an example of an X1 area of FIG. 1. FIG. 20 is an enlarged schematic plan view illustrating an example of an X2 area of FIG. 1.

A display device according to embodiments described with reference to FIGS. 19 and 20 may be substantially same as or similar to the display device (e.g., the display device DD of FIG. 1) described with reference to FIGS. 2 and 3 except for position and number of multiple alignment patterns. Accordingly, redundant description may be omitted or simplified.

Referring to FIGS. 19 and 20, multiple alignment patterns may be disposed on a substrate SUB. For example, a first alignment pattern PNL-AM1′, a second alignment pattern PNL-AM2′, a third alignment pattern PNL-AM3′, a fourth alignment pattern PNL-AM4′, a fifth alignment pattern PNL-AM5′, a sixth alignment pattern PNL-AM6′, a seventh alignment pattern PNL-AM7′, an eighth alignment pattern PNL-AM8′, a ninth alignment pattern PNL-AM9′, and a tenth alignment pattern PNL-AM10′ may be disposed on the substrate SUB.

One alignment pattern may be disposed between adjacent film pads. For example, the second alignment pattern PNL-AM2′ may be disposed between the first film pad COF-P1 and the second film pad COF-P2. The third alignment pattern PNL-AM3′ may be disposed between the second film pad COF-P2 and the third film pad COF-P3. The fourth alignment pattern PNL-AM4′ may be disposed between the third film pad COF-P3 and the fourth film pad COF-P4. The first alignment pattern PNL-AM1′ may be spaced apart from the second alignment pattern PNL-AM2′ in the direction opposite to the first direction DR1. For example, the first alignment pattern PNL-AM1′ may be spaced apart from the second alignment pattern PNL-AM2′ with respect to the first film pad COF-P1 interposed therebetween in a plan view. The fifth alignment pattern PNL-AM5′ may be spaced apart from the fourth alignment pattern PNL-AM4′ in the first direction DR1. For example, the fifth alignment pattern PNL-AM5′ may be spaced apart from the fourth alignment pattern PNL-AM4′ with respect to the fourth film pad COF-P4 interposed therebetween in a plan view.

For example, the seventh alignment pattern PNL-AM7′ may be disposed between the fifth film pad COF-P5 and the sixth film pad COF-P6. The eighth alignment pattern PNL-AM8′ may be disposed between the sixth film pad COF-P6 and the seventh film pad COF-P7. The ninth alignment pattern PNL-AM9′ may be disposed between the seventh film pad COF-P7 and the eighth film pad COF-P8. The sixth alignment pattern PNL-AM6′ may be spaced apart from the seventh alignment pattern PNL-AM7′ in the first direction DR1. For example, the sixth alignment pattern PNL-AM6′ may be spaced apart from the seventh alignment pattern PNL-AM7′ with respect to the fifth film pad COF-P5 interposed therebetween in a plan view. The tenth alignment pattern PNL-AM10′ may be spaced apart from the ninth alignment pattern PNL-AM9′ in the direction opposite to the first direction DR1. For example, the tenth alignment pattern PNL-AM10′ may be spaced apart from the ninth alignment pattern PNL-AM9′ with respect to the eighth film pad COF-P8 interposed therebetween in a plan view.

As described above, in case that the chip-on-film COF is attached to the substrate SUB in a contracted or expanded position, the position of the chip-on-film COF may be adjusted. For example, in case that the chip-on-film COF is expanded, the chip-on-film COF may move in the second direction DR2. Thereafter, it may be necessary to check whether multiple substrate pads and multiple film pads are aligned, respectively. For example, it is necessary to check whether the position of the chip-on-film COF is adjusted.

By measuring separation distance between the first alignment pattern PNL-AM1′ and the first film pad COF-P1 and separation distance between the second alignment pattern PNL-AM2′ and the first film pad COF-P1, it may be checked whether the position of the chip -on-film COF is adjusted.

By measuring distance between the second alignment pattern PNL-AM2′ and the second film pad COF-P2 and separation distance between the third alignment pattern PNL-AM3′ and the second film pad COF-P2, it may be checked whether the position of the chip-on-film COF is adjusted.

By measuring distance between the third alignment pattern PNL-AM3′ and the third film pad COF-P3 and separation distance between the fourth alignment pattern PNL-AM4′ and the third film pad COF-P3, it may be checked whether the position of the chip-on-film COF is adjusted.

By measuring distance between the fourth alignment pattern PNL-AM4′ and the fourth film pad COF-P4 and separation distance between the fifth alignment pattern PNL-AM5′ and the fourth film pad COF-P4, it may be checked whether the position of the chip-on-film COF is adjusted.

By measuring distance between the sixth alignment pattern PNL-AM6′ and the fifth film pad COF-P5 and separation distance between the seventh alignment pattern PNL-AM7′ and the fifth film pad COF-P5, it may be checked whether the position of the chip-on-film COF is adjusted.

By measuring separation distance between the seventh alignment pattern PNL-AM7′ and the sixth film pad COF-P6 and separation distance between the eighth alignment pattern PNL-AM8′ and the sixth film pad COF-P6, it may be checked whether the position of the chip-on-film COF is adjusted.

By measuring separation distance between the eighth alignment pattern PNL-AM8′ and the seventh film pad COF-P7 and separation distance between the ninth alignment pattern PNL-AM9′ and the seventh film pad COF-P7, it may be checked whether the position of the chip-on-film COF is adjusted.

By measuring separation distance between the ninth alignment pattern PNL-AM9′ and the eighth film pad COF-P8 and separation distance between the tenth alignment pattern PNL-AM10′ and the eighth film pad COF-P8, it may be checked whether the position of the chip-on-film COF is adjusted.

The display device (e.g., the display device DD of FIG. 1) according to embodiments may be applied to various electronic devices. An electronic device according to embodiments may include the above-described display device, and may further include a module or device having other additional functions in addition to the display device.

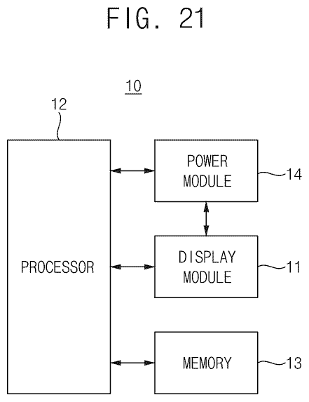

FIG. 21 is a schematic block diagram illustrating an electronic device according to embodiments.

Referring to FIG. 21, an electronic device 10 according to embodiments may include a display module 11, a processor 12, a memory 13, and a power module 14.

The processor 12 may include at least one of a central processing unit (“CPU”), an application processor (“AP”), a graphic processing unit (“GPU”), a communication processor (“CP”), an image signal processor (“ISP”), and a controller.

Data information necessary for operation of the processor 12 or the display module 11 may be stored in the memory 13. In case that the processor 12 executes an application stored in the memory 13, an image data signal and/or an input control signal is transmitted to the display module 11, and the display module 11 may process received signal and output image information through a display screen.

The power module 14 may include a power supply module such as a power adapter or a battery device, and a power conversion module that converts power supplied by the power supply module to generate power required for operation of the electronic device 10.

At least one of components of the electronic device 10 described above may be included in the display device according to the above-described embodiments. In addition, some of individual modules functionally included in one module may be included in the display device, and others may be provided separately from the display device. For example, the display device may include the display module 11, and the processor 12, the memory 13, and the power module 14 may be provided in form of another device in the electronic device 10 other than the display device.

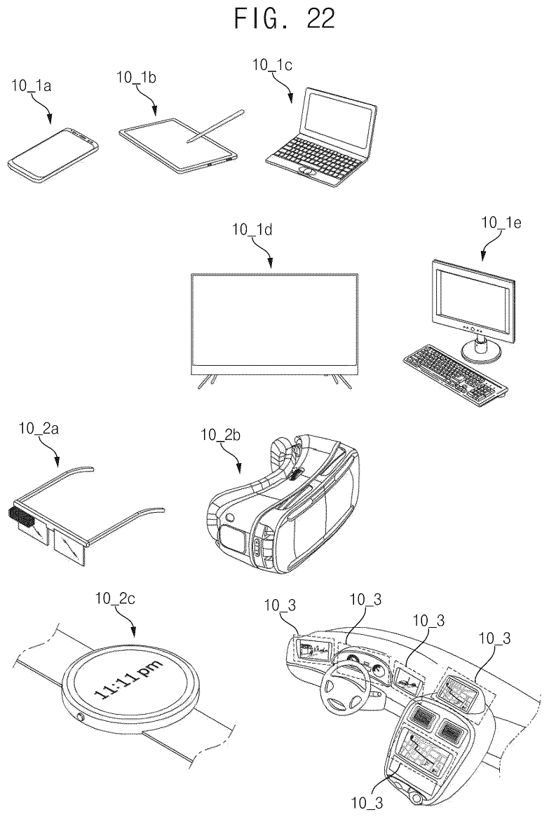

FIG. 22 is a schematic diagram of an electronic device according to various embodiments.

Referring to FIG. 22, various electronic devices to which display devices according to embodiments are applied may include not only electronic devices for image display such as a smartphone 10_1a, a tablet PC 10_1b, a laptop 10_1c, a TV 10_1d, a desk monitor 10_1e, and/or the like, but also wearable electronic devices including display modules such as a smart glass 10_2a, a head mounted display 10_2b, a smart watch 10_2c for a virtual reality (VR), a mixed reality (MR), and an augmented reality (AR), and/or the like, vehicle electronic device 10_3 including display modules such as a vehicle's instrument panel, a center fascia, a center information display (“CID”) disposed on a dashboard, a room mirror display, and/or the like.

The disclosure can be applied to various display devices. For example, the disclosure is applicable to various display devices such as display devices for vehicles, ships and aircraft, portable communication devices, display devices for exhibition or information transmission, medical display devices, and the like.

The foregoing is illustrative of embodiments and is not to be construed as limiting thereof. Although a few embodiments have been described, those skilled in the art will readily appreciate that many modifications are possible in the embodiments without materially departing from the novel teachings and advantages of the present inventive concept. Accordingly, all such modifications are intended to be included within the scope of the present inventive concept as defined in the claims. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims.

What is claimed is:

1. A display device comprising:
a substrate including a display area in which a plurality of pixels are disposed and a pad area spaced apart from the display area;
a first substrate pad disposed in the pad area on the substrate and forming a first inclination angle with respect to an edge of the substrate to have an inclined shape;
a substrate alignment mark disposed in the pad area on the substrate and adjacent to the first substrate pad;
a first alignment pattern disposed in the pad area on the substrate and disposed below the first substrate pad in a plan view; and
a chip-on-film attached to a side of the substrate, the chip-on-film including:
a first film pad overlapping the first substrate pad in a plan view in at least a portion of the pad area and forming a second inclination angle with respect to the edge of the substrate to have an inclined shape; and
a film alignment mark adjacent to the first film pad.

2. The display device of claim 1, wherein the first inclination angle and the second inclination angle are substantially equal to each other.

3. The display device of claim 1, wherein the first alignment pattern forms a third inclination angle with respect to the edge of the substrate, and
the third inclination angle and the first inclination angle are substantially equal to each other.

4. The display device of claim 1, wherein the substrate alignment mark is adjacent to the first substrate pad in a first direction, and
the film alignment mark is adjacent to the first film pad in the first direction.

5. The display device of claim 4, wherein the first alignment pattern is adjacent to the first film pad in the first direction in a plan view.

6. The display device of claim 5, further comprising:
a second alignment pattern spaced apart from the first alignment pattern in a plan view with the first film pad disposed between the second alignment pattern and the first alignment pattern.

7. The display device of claim 6, wherein the first alignment pattern forms a third inclination angle with respect to the edge of the substrate to have an inclined shape,
the second alignment pattern forms a fourth inclination angle with respect to the edge of the substrate, and
the third inclination angle and the fourth inclination angle are substantially equal to each other.

8. The display device of claim 1, further comprising:
a second substrate pad disposed in the pad area on the substrate, disposed adjacent to the first substrate pad, and forming a third inclination angle with respect to the edge of the substrate to have an inclined shape.

9. The display device of claim 8, wherein the chip-on-film further includes a second film pad overlapping the second substrate pad in a plan view in at least a portion of the pad area and forming a fourth inclination angle with respect to the edge of the substrate, and
the third inclination angle and the fourth inclination angle are substantially equal to each other.

10. The display device of claim 9, further comprising:
a second alignment pattern disposed in the pad area on the substrate and spaced apart from the first alignment pattern in a plan view with respect to the first film pad;
a third alignment pattern disposed between the second alignment pattern and the second film pad in a plan view; and
a fourth alignment pattern disposed in the pad area on the substrate and spaced apart from the third alignment pattern in a plan view with respect to the second film pad.

11. The display device of claim 10, wherein the third alignment pattern forms a fifth inclination angle with respect to the edge of the substrate to have an inclined shape,
the fourth alignment pattern forms a sixth inclination angle with respect to the edge of the substrate, and
the fifth inclination angle and the sixth inclination angle are equal to each other.

12. The display device of claim 1, wherein the first alignment pattern is a portion from which at least a portion of an insulating layer disposed on the first substrate pad is removed.

13. A method of manufacturing a display device, the method comprising:
attaching a chip-on-film to a side of a substrate including a display area in which a plurality of pixels are disposed and a pad area spaced apart from the display area;
checking a substrate alignment mark disposed in the pad area on the substrate and a film alignment mark included in the chip-on-film to check whether the chip-on-film is expanded and whether the chip-on-film is contracted;
adjusting position of the chip-on-film; and
measuring a first separation distance between a first film pad and a first alignment pattern adjacent to the first film pad, wherein the first film pad is included in the chip-on-film and forms a first inclination angle with respect to an edge of the substrate to have an inclined shape in at least a portion of the pad area.

14. The method of claim 13, wherein the adjusting of the position of the chip-on-film includes moving the chip-on-film in a direction away from the substrate in case that the chip-on-film is expanded.

15. The method of claim 13, wherein the adjusting of the position of the chip-on-film includes moving the chip-on-film so that an area where the chip-on-film and the substrate overlap in a plan view increases in case that the chip-on-film is contracted.

16. The method of claim 13, further comprising:
additionally adjusting the position of the chip-on-film after measuring the first separation distance between the first film pad and the first alignment pattern.

17. An electronic device comprising:
a substrate including a display area in which a plurality of pixels are disposed and a pad area spaced apart from the display area;
a first substrate pad disposed in the pad area on the substrate and forming a first inclination angle with respect to an edge of the substrate to have an inclined shape;
a substrate alignment mark disposed in the pad area on the substrate and adjacent to the first substrate pad;
a first alignment pattern disposed in the pad area on the substrate and disposed below the first substrate pad in a plan view;
a chip-on-film attached to a side of the substrate, the chip-on-film including:
a first film pad overlapping the first substrate pad in a plan view in at least a portion of the pad area and forming a second inclination angle with respect to the edge of the substrate to have an inclined shape; and
a film alignment mark adjacent to the first film pad; and
memory where data information is stored.

18. The electronic device of claim 17, wherein the first inclination angle and the second inclination angle are substantially equal to each other.

19. The electronic device of claim 17, wherein the first alignment pattern forms a third inclination angle with respect to the edge of the substrate, and
the third inclination angle and the first inclination angle are substantially equal to each other.

20. The electronic device of claim 17, wherein the substrate alignment mark is adjacent to the first substrate pad in a first direction, and
the film alignment mark is adjacent to the first film pad in the first direction.
